(19) United States
(12) Patent Application Publication
(10) Pub. No.: US 2023/0335405 A1
(43) Pub. Date: Oct. 19, 2023

(54) COMPUTATIONAL REPRESENTATION OF DEPOSITION PROCESSES

(71) Applicant: Lam Research Corporation, Fremont, CA (US)

(72) Inventors: Qing Peng Wang, Shanghai (CN); Yu De Chen, Taiwan (CN); Shi Hao Huang, Taiwan (CN); Rui Bao, Shanghai (CN); Joseph Ervin, San Jose, CA (US)

(21) Appl. No.: 18/006,639

(22) PCT Filed: Jul. 26, 2021
(86) PCT No.: PCT/US2021/043233

§ 371 Date: Jan. 24, 2023

Related U.S. Application Data
(60) Provisional application No. 62/706,037, filed on Jul. 28, 2020.

(51) Int. Cl. H01L 21/288; H01L 21/768; C25D 21/12; C25D 5/02

(52) U.S. Cl. CPC H01L 21/2885; C25D 5/02; C25D 21/12; H01L 21/76879

(57) ABSTRACT

A system, method, and/or non-transitory computer readable medium may implement or be configured to implement the following computational operations associated with electrochemical or vapor phase deposition: (a) defining an interface of a substrate where deposition of a deposited material is to occur or is occurring; (b) using a computational model of the deposition to determine a local deposition rate of the deposited material at multiple locations on the interface, where the computational model of the deposition computes the local deposition rate as a function of one or more geometric parameters of the one or more recessed or protruding features; and (c) computationally adjusting the location of the interface to produce an adjusted interface.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

The performance of semiconductor device fabrication operations such as electrochemical deposition processes is often essential to the success of a semiconductor device processing workflow. However, optimization or tuning of such processes and/or the tools associated with them (e.g., electroplating cells) may prove technically difficult and time-consuming, often involving skilled personnel manually adjusting process parameters or tool component designs to generate the desired target feature profile. Currently, no automated procedure of sufficient accuracy exists to determine the values of process parameters responsible for a desired deposition profile.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Certain aspects of this disclosure pertain to systems that include one or more processors, which systems are configured to computationally execute instructions for: (a) defining an interface of a substrate where deposition of a deposited material is to occur or is occurring, wherein the interface comprises one or more recessed or protruding features extending vertically into or above a surface of the substrate; (b) using a computational model of the deposition to determine a local deposition rate of the deposited material at multiple locations on the interface, wherein the computational model of the deposition computes the local deposition rate as a function of one or more geometric parameters of the one or more recessed or protruding features; and (c) computationally adjusting the location of the interface to produce an adjusted interface, wherein adjusting the interface applies the deposited material in a manner that accounts for the local deposition rate of the deposited material at the multiple locations on the interface.

In certain embodiments, the instructions of the system pertain to an electrochemical deposition. And, in the context of electrochemical deposition, the computational model may be configured to account for a concentration of a chemical species. In some cases, the chemical species comprise hydrogen ions. In some embodiments, a computational model pertaining to electrochemical deposition comprises a plurality of fixed parameters, and the plurality of fixed parameters may comprise a characteristic baseline deposition rate of the electrochemical deposition and a characteristic diffusion length of one or more chemical species. In some implementations, instructions include instructions for iteratively repeating operations (b) and (c) until determining that an overburden of the deposited material is produced over one or more recessed features of the surface of the substrate.

In certain embodiments, the instructions of the system pertain to a vapor deposition such as a chemical vapor deposition. In some system embodiments, pertaining to vapor deposition, the computational model comprises a linear expression of the local curvature in or on the one or more recessed or protruding features. In some system embodiments, pertaining to vapor deposition, the computational model comprises one or more fixed parameters, and the one or more fixed parameters comprise a characteristic baseline deposition rate of the vapor deposition and a ratio of a lateral deposition rate to a vertical deposition rate.

In certain embodiments, regardless of type of deposition, the system is configured to computationally execute instructions for iteratively repeating operations (b) (using the model to determine a local deposition rate) and (c) (adjusting the location of the interface). In some cases, the instructions for iteratively repeating operations (b) and (c) comprise instructions for repeating operations (b) and (c) until determining that the one or more recessed features of the surface of the substrate are fully filled with the deposited material.

In certain embodiments, the computational model of deposition is a behavioral model. In certain embodiments, the computational model is configured to account for a concentration of a chemical species that varies as a function of the vertical position in or on the one or more recessed or protruding features. As an example, the chemical species may be a chemical species that adsorbs on the features of the surface of the substrate. In certain embodiments, the computational model is configured to account for a concentration gradient along sidewalls of the one or more recessed or protruding features.

In some implementations, the computation model is configured to determine the local deposition rate as a function of a vertical position in or on the one or more recessed or protruding features. In some implementations, the computational model of deposition comprises an exponential function of the vertical position in or on the one or more recessed or protruding features. In some implementations, the local deposition rate is determined as a function of a local curvature in or on the one or more recessed or protruding features.

In certain embodiments, the computational model contains only two fixed parameters. In certain embodiments, the computational model contains only one variable and the only one variable is the vertical position in or on the one or more recessed or protruding features. In certain embodiments, the computational model contains only one variable and the only one variable is the local curvature in or on the one or more recessed or protruding features.

In certain embodiments, the instructions for computationally adjusting the location of the interface comprise instructions for applying geometric objects to the multiple locations on the interface, where the geometric objects have a dimension that varies in size based at least in part on the local deposition rate of the deposited material on the multiple locations. In one example, the geometric objects are circles or spheres. In one example, the geometric objects are ellipses or ellipsoids. In some implementations, the geometric objects have a first axis and a second axis and wherein a ratio of the length of the first axis to the length of the second axis corresponds to a ratio of a lateral deposition rate of the vapor deposition to a vertical deposition rate of the vapor deposition.

Certain aspects of this disclosure pertain to computational methods that may include the following operations: (a) defining an interface of a substrate where deposition of a deposited material is to occur or is occurring, wherein the interface comprises one or more recessed or protruding features extending vertically into or above a surface of the substrate; (b) using a computational model of the deposition to determine a local deposition rate of the deposited material at multiple locations on the interface, wherein the computational model of the deposition computes the local deposition rate as a function of one or more geometric parameters of the one or more recessed or protruding features; and (c) computationally adjusting the location of the interface to produce an adjusted interface, wherein adjusting the interface applies the deposited material in a manner that accounts for the local deposition rate of the deposited material at the multiple locations on the interface.

In certain embodiments, the operations of the method pertain to an electrochemical deposition. And, in the context of electrochemical deposition, the computational model may be configured to account for a concentration of a chemical species. In some cases, the chemical species comprise hydrogen ions. In some embodiments, a computational model pertaining to electrochemical deposition comprises a plurality of fixed parameters, and the plurality of fixed parameters may comprise a characteristic baseline deposition rate of the electrochemical deposition and a characteristic diffusion length of one or more chemical species. In some implementations, operations include iteratively repeating operations (b) and (c) until determining that an overburden of the deposited material is produced over one or more recessed features of the surface of the substrate.

In certain embodiments, the operations of the method pertain to a vapor deposition such as a chemical vapor deposition. In some method embodiments, pertaining to vapor deposition, the computational model comprises a linear expression of the local curvature in or on the one or more recessed or protruding features. In some method embodiments, pertaining to vapor deposition, the computational model comprises one or more fixed parameters, and the one or more fixed parameters comprise a characteristic baseline deposition rate of the vapor deposition and a ratio of a lateral deposition rate to a vertical deposition rate.

In certain embodiments, regardless of type of deposition, the method comprises iteratively repeating operations (b) (using the model to determine a local deposition rate) and (c) (adjusting the location of the interface). In some cases, iteratively repeating operations (b) and (c) comprises repeating operations (b) and (c) until determining that the one or more recessed features of the surface of the substrate are fully filled with the deposited material.

In certain embodiments, the computational model of deposition is a behavioral model. In certain embodiments, the computational model is configured to account for a concentration of a chemical species that varies as a function of the vertical position in or on the one or more recessed or protruding features. As an example, the chemical species may be a chemical species that adsorbs on the features of the surface of the substrate. In certain embodiments, the computational model is configured to account for a concentration gradient along sidewalls of the one or more recessed or protruding features.

In some implementations, the computation model is configured to determine the local deposition rate as a function of a vertical position in or on the one or more recessed or protruding features. In some implementations, the computational model of deposition comprises an exponential function of the vertical position in or on the one or more recessed or protruding features. In some implementations, the local deposition rate is determined as a function of a local curvature in or on the one or more recessed or protruding features.

In certain embodiments, the computational model contains only two fixed parameters. In certain embodiments, the computational model contains only one variable and the only one variable is the vertical position in or on the one or more recessed or protruding features. In certain embodiments, the computational model contains only one variable and the only one variable is the local curvature in or on the one or more recessed or protruding features.

In certain embodiments, computationally adjusting the location of the interface comprises applying geometric objects to the multiple locations on the interface, where the geometric objects have a dimension that varies in size based at least in part on the local deposition rate of the deposited material on the multiple locations. In one example, the geometric objects are circles or spheres. In one example, the geometric objects are ellipses or ellipsoids. In some implementations, the geometric objects have a first axis and a second axis and wherein a ratio of the length of the first axis to the length of the second axis corresponds to a ratio of a lateral deposition rate of the vapor deposition to a vertical deposition rate of the vapor deposition.

Certain aspects of this disclosure pertain to non-transitory computer-readable media that may store computer executable instructions for: (a) defining an interface of a substrate where deposition of a deposited material is to occur or is occurring, wherein the interface comprises one or more recessed or protruding features extending vertically into or above a surface of the substrate; (b) using a computational model of the deposition to determine a local deposition rate of the deposited material at multiple locations on the interface, wherein the computational model of the deposition computes the local deposition rate as a function of one or more geometric parameters of the one or more recessed or protruding features; and (c) computationally adjusting the location of the interface to produce an adjusted interface, wherein adjusting the interface applies the deposited material in a manner that accounts for the local deposition rate of the deposited material at the multiple locations on the interface.

In certain embodiments, the instructions stored on the computer-readable medium pertain to an electrochemical deposition. And, in the context of electrochemical deposition, the computational model may be configured to account for a concentration of a chemical species. In some cases, the chemical species comprise hydrogen ions. In some embodiments, a computational model pertaining to electrochemical deposition comprises a plurality of fixed parameters, and the plurality of fixed parameters may comprise a characteristic baseline deposition rate of the electrochemical deposition and a characteristic diffusion length of one or more chemical species. In some implementations, instructions stored on the computer-readable medium include instructions for iteratively repeating operations (b) and (c) until determining that an overburden of the deposited material is produced over one or more recessed features of the surface of the substrate.

In certain embodiments, the instructions stored on the computer-readable medium pertain to a vapor deposition such as a chemical vapor deposition. In some computer-readable medium embodiments, pertaining to vapor deposition, the computational model comprises a linear expression of the local curvature in or on the one or more recessed or protruding features. In some computer-readable medium embodiments, pertaining to vapor deposition, the computational model comprises one or more fixed parameters, and the one or more fixed parameters comprise a characteristic baseline deposition rate of the vapor deposition and a ratio of a lateral deposition rate to a vertical deposition rate.

In certain embodiments, regardless of type of deposition, the computer readable medium comprises instructions for iteratively repeating operations (b) (using the model to determine a local deposition rate) and (c) (adjusting the location of the interface). In some cases, the instructions for iteratively repeating operations (b) and (c) comprise instructions for repeating operations (b) and (c) until determining that the one or more recessed features of the surface of the substrate are fully filled with the deposited material.

In certain embodiments, the computational model of deposition is a behavioral model. In certain embodiments, the computational model is configured to account for a concentration of a chemical species that varies as a function of the vertical position in or on the one or more recessed or protruding features. As an example, the chemical species may be a chemical species that adsorbs on the features of the surface of the substrate. In certain embodiments, the computational model is configured to account for a concentration gradient along sidewalls of the one or more recessed or protruding features.

In some implementations, the computation model is configured to determine the local deposition rate as a function of a vertical position in or on the one or more recessed or protruding features. In some implementations, the computational model of deposition comprises an exponential function of the vertical position in or on the one or more recessed or protruding features. In some implementations, the local deposition rate is determined as a function of a local curvature in or on the one or more recessed or protruding features.

In certain embodiments, the computational model contains only two fixed parameters. In certain embodiments, the computational model contains only one variable and the only one variable is the vertical position in or on the one or more recessed or protruding features. In certain embodiments, the computational model contains only one variable and the only one variable is the local curvature in or on the one or more recessed or protruding features.

In certain embodiments, the instructions for computationally adjusting the location of the interface comprise instructions for applying geometric objects to the multiple locations on the interface, where the geometric objects have a dimension that varies in size based at least in part on the local deposition rate of the deposited material on the multiple locations. In one example, the geometric objects are circles or spheres. In one example, the geometric objects are ellipses or ellipsoids. In some implementations, the geometric objects have a first axis and a second axis and wherein a ratio of the length of the first axis to the length of the second axis corresponds to a ratio of a lateral deposition rate of the vapor deposition to a vertical deposition rate of the vapor deposition.

These and other features of the disclosure will be presented below with reference to the associated drawings.

### BRIEF DESCRIPTION OF THE DRAWINGS

FIG. 1 presents micrographs of a cross-sectional profile at three stages of a bottom-up electrofill process in recessed features of a substrate.

FIGS. 2A and 2B show schematically a bottom-up fill process for cobalt in the presence of a gradient of adsorbed hydrogen ions on a sidewall of a recessed feature.

FIG. 3A presents a process flow chart for an example computational process of simulating an electrodeposition process.

FIG. 3B presents a computational process embodiment mirroring that of FIG. 3A but including more illustrations of the possible implementations of certain process operations.

FIG. 4 presents a computational process embodiment for simulating a bottom up electrofill process.

FIG. 5 presents a computational embodiment that positions geometric objects on a substrate interface as part of a simulation of an electrochemical deposition process.

FIG. 6 presents an example process flow for simulating a bottom up electrochemical deposition process.

FIG. 7 illustrates an example vapor deposition process for filling a stepped, recessed feature with a fill material.

FIG. 8 illustrates a feature being filled in accordance with an example of a vapor deposition simulation (e.g., a simulation of a CVD or ALD process).

FIG. 9 depicts an embodiment for computationally determining the curvature of a contour at the interface of a substrate and vapor.

FIG. 10 illustrates an example of a computational process for determining the time evolving profile of a substrate-vapor interface during a vapor deposition process.

FIG. 11 presents an example process flow for modeling a vapor deposition process in a stepped, recessed feature.

FIG. 12 illustrates a process of computationally modifying voxels during an iteration of a simulated vapor deposition process.

FIG. 13 illustrates an example simulation of a vapor deposition process.

FIG. 14 depicts an example of user interface displaying parameter values for a simulation of an electrodeposition process.

FIG. 15 depicts an example user interface displaying parameter values for a vapor deposition process simulation.

FIG. 16 shows an example computational system that may be used to execute process simulation models.

FIG. 17A illustrates that electrofill model results in a substrate having different feature depths match actual electrofill results shown in micrographs.

FIG. 17B illustrates electrofill simulation results for multiple runs using different mass transfer parameter values (diffusion length values in this example).

FIG. 17C presents an electrofill simulation’s results in a substrate having features with different critical dimensions.

FIG. 17D illustrates electrofill simulation results for runs using different feature profiles, particularly different side wall angles in a recessed feature.

FIG. 18A presents an example comparing a simulation result with a real result for vapor depositing an oxide.

FIG. 18B illustrates flexibility of the computational simulation to match various actual vapor deposition results by choosing combinations of the adjustable parameters.

### DETAILED DESCRIPTION

### Introduction and Context

Disclosed herein are behavioral models and their use to predict the result of deposition in a substrate having recesses and/or protrusions. The deposition process is modeled based on, e.g., reaction rate parameters and feature geometry.

In certain embodiments, the behavioral model is designed or configured to model electrochemical fill processing. In certain embodiments, the behavioral model is designed or configured to model bottom-up electrofill in recessed features. In certain embodiments, modes account for concentration gradients of a species such as hydrogen ions from top to bottom within the feature to be electrofilled.

While many of the examples herein pertain to electrofill of cobalt, the disclosure is not limited to this application. It applies to any electrofill process, including those for depositing nickel, copper, tin, silver, molybdenum, and alloys of any of these. In some cases, models are designed or configured to predict electrofill properties in features in the 7 nanometer and sub 7 nanometer technology node.

In certain embodiments, a behavioral model is designed or configured to model a vapor deposition process. In certain embodiments, the behavioral model is designed or configured to model a vapor deposition process in recessed features. In certain embodiments, a vapor deposition model accounts for surface curvature variations in recessed feature to be filled.

While many of the examples herein pertain to vapor deposition in a stepped feature, the disclosure is not limited to this application. It applies to any vapor process, including those for depositing on protruding structures and non-stepped features.

In certain embodiments, the behavioral model is designed or configured to computationally execute the following operations:

1. Find an initial interface where deposition will occur. The interface may be a substrate surface having recessed and/or protruding features represented in two or three dimensions.

2. Determine a deposition rate at each of multiple points (voxels) on the interface. The deposition rate may account for feature geometry and/or the chemistry and/or physics of the deposition process. The geometry may account for, e.g., feature depth or height, feature curvature, feature aspect ratio, and the like. The chemistry and/or physics of the deposition process may account for diffusion of one or more species in a deposition medium, kinetics of a surface reaction, convection in the deposition medium, and/or similar considerations.

3. Apply a geometric adjustment at the locations of each of the multiple points on the interface where the deposition rate was determined in 2. The geometric adjustment may scale in at least one dimension with the magnitude of the deposition rates determined in 2. In certain embodiments, a geometric adjustment is application of a fill element such as an ellipsoid or circle at an interface location where the deposition rate is determined.

4. To the extent not fully accomplished in 3, define a new interface where deposition will continue to occur. In certain embodiments, this involves smoothing or otherwise adjusting a profile created by the edges of fill elements.

5. Iteratively repeat operations 2-4, with each iteration corresponding to time evolution. The process may end when the amount of deposition and/or the representative time elapsed passes a threshold.

In certain embodiments, a behavioral deposition model is applicable in only certain geometric or physical realms. For example, in some implementations, an electrofill model is applicable in electroplating cells employing electroplating solutions and operating conditions configured to provide bottom-up fill. In some implementations, an electrofill model is applicable in substrates having recesses having aspect ratios, on average, of at least about 2:1.

### Terminology

The terms “semiconductor wafer,” “wafer,” “substrate,” and “wafer substrate” may be used interchangeably. Those of ordinary skill in the art understand that the term “partially fabricated integrated circuit” can refer to any of one or more devices on a semiconductor wafer during any of many stages of integrated circuit fabrication thereon. A wafer or substrate used in the semiconductor device industry typically has a diameter of 200 mm, or 300 mm, or 450 mm. This disclosure presents embodiments implemented on a “wafer.” It should be understood that such references to “wafer” extend to other types of work piece. A work piece may be of various shapes, sizes, and materials. Besides semiconductor wafers, examples of work pieces that may be employed in the disclosed embodiments include printed circuit boards, magnetic recording media, magnetic recording sensors, mirrors, optical elements, micro-mechanical devices, and the like.

A semiconductor device fabrication operation or fabrication operation may be an operation performed during fabrication of semiconductor devices. For example, the overall fabrication process may include multiple semiconductor device fabrication operations, each performed in its own semiconductor fabrication tool such as a plasma reactor, an electroplating cell, an annealing chamber, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition).

A deposition process may be one that adds material and/or volume to a surface of a substrate. The added volume may occupy space that was previously unfilled such as space that was occupied by a gas, a vacuum, or a liquid such as an electrolyte. A deposition process may leave the underlying substrate unmodified (chemically and/or physically), or a deposition process may chemically or physically modify an underlying substrate. In some embodiments, a deposition process deposits a material that is physically and chemically different from the substrate. In some embodiments, the deposition process is an electrochemical deposition process such as electroplating or electroless plating. In some embodiments, the deposition process is a vapor deposition process such as chemical vapor deposition, physical vapor deposition, or atomic layer deposition. In some embodiments, the deposition process is an epitaxial growth process. In some embodiments, the underlying substrate is chemically modified through oxidation or other reaction. As an example, a deposition process on a metal substrate may produce a metal oxide layer that contain some metal atoms that were originally in the substrate.

A process chamber, manufacturing equipment, and fabrication tool may be equipment in which a manufacturing process takes place. Manufacturing equipment may have a processing chamber in which the workpiece resides during processing. In some instances, when in use, manufacturing equipment performs one or more semiconductor device fabrication operations. Examples of manufacturing equipment for semiconductor device fabrication include additive process reactors such as electroplating cells, physical vapor deposition reactors, chemical vapor deposition reactors, and atomic layer deposition reactors. Examples of subtractive process reactors include dry etch reactors (e.g., chemical and/or physical etch reactors), wet etch reactors, and ashers. Other types of manufacturing equipment include annealing chambers and cleaning devices.

A feature may be an unfilled, partially filled, or completely filled recess on a substrate. A through-silicon via may be unfilled, partially filled or completely filled recessed via formed in a silicon or other material substrate. Features may have different depths, different loadings, different shapes when viewed top down toward the substrate, and combinations thereof. In some embodiments, some features of the substrate may have round, oblong, or rectangular shapes when viewed from above. In some embodiments, at least some features on a substrate have an aspect ratio equal to or greater than about 2:1, equal to or greater than about 5:1, or equal to or greater than about 10:1.

A process simulation model or model may be configured to predict a result of a semiconductor device fabrication operation. For example, such a model may be configured to output the result. A process simulation model may predict such result by using process parameter values characterizing the substrate and/or the fabrication operation. Examples of results include feature profiles (e.g., detailed Cartesian coordinates of a feature), profile parameters characterizing a feature (e.g., critical dimension, sidewall angles, depth, etc.), and the like. The results are based on features produced or modified during the simulated semiconductor device fabrication operation. The results may be predicted at one or more times during the semiconductor device fabrication operation.

Inputs to the process simulation model include one or more process parameter values that characterize the semiconductor device substrate and/or fabrication operation. Process parameters used as inputs may include geometric characteristics of the substrate interface on which processing occurs, behavioral characteristics of the process such as non-mechanistic characteristics, reactor conditions such as temperature (pedestal, showerhead, etc.), plasma conditions (density, potential, power, etc.), process gas conditions (composition such partial pressures of components, flow rate, pressure, etc.), and the like. In various embodiments, a process simulation model receives an initial profile substrate, which represents the profile of the substrate surface (an interface) immediately before being processed via the modeled semiconductor device fabrication operation. In certain embodiments, an initial profile has recessed or protruding features such as trench, via, mask, or photoresist features.

The initial profile may be generated computationally using information about a fabrication step that precedes the semiconductor device fabrication operation. Alternatively, the initial profile is generated by conducting metrology on a substrate surface produced from the fabrication step that precedes the semiconductor device fabrication operation. During a semiconductor device fabrication operation, real or simulated, the substrate surface is modified from the initial profile to a final profile.

Sometimes, the process simulation model simulates a subtractive process such as a substrate etch process or a planarization process. In various embodiments, the process simulation model simulates an additive process such as a substrate deposition process (e.g., chemical vapor deposition, physical vapor deposition, atomic layer deposition, electrochemical fill, etc.).

A computationally predicted result of a semiconductor device fabrication operation as used herein is a predicted result of the semiconductor device fabrication operation produced computationally such as by a computational model, e.g., a process simulation model for the device fabrication operation under consideration. In certain embodiments, a computational process calculates a predicted feature profile represented by geometric profile coordinates. In some embodiments, feature profiles, optical responses, and/or profile parameters are computed as a function of time (over which the semiconductor device fabrication operation occurs). In certain embodiments, to predict the result of the semiconductor device fabrication operation, the computation process predicts local reaction rates at a grid of points representing a feature profile on a semiconductor substrate. This results in a substrate/feature profile that deviates from an initial profile used at the beginning of the computations.

Process simulation models may simulate the “evolution” of a substrate surface profile, e.g., sequential changes to a feature’s deposition profile as measured over time, or time-dependent changes in the shape of a feature at various spatial locations on the feature’s surface, by calculating reaction rates or other process parameters associated with the deposition process at each of many spatial locations. Variance in the reaction rates may result from local geometry of the substrate interface, flux of reactant, the characteristics of the selected deposition material, or any of a number of other factors. Further, calculated reaction rates may fluctuate over the course of the simulated etch process. Not all process simulation models simulate the evolution over the course of a semiconductor device fabrication operation; some simply predict the final profile given reaction conditions (including the duration of the operation) and an initial feature profile.

In some embodiments, output of a simulated etch profile may be represented by a discrete set of data points, i.e. profile coordinates or voxels that spatially define and/or otherwise map out the shape of the profile. The simulated deposition profile’s evolution over time depends on the modelled, spatially resolved local deposition rates which, in turn, depend on the underlying chemistry and physics of the etch process.

Certain models simulate the physical and/or chemical processes occurring on semiconductor substrate surfaces during deposition processes. Examples of such models include deposition models implemented as behavioral models. Behavioral models may employ abstractions of processes to predict structural details of features produced by one or more semiconductor device fabrication operations. One example of a behavioral model is the SEMulator3D™ from Coventor, a Lam Research Company. Examples of behavioral models are presented in U.S. Pat. No. 9,015,016 and U.S. Pat. No. 9,659,126, both previously incorporated by reference.

A behavioral model may be specific to the type of deposition and the material being deposited. This allows the capture of a wide range of physical deposition behavior without the need to directly simulate the physics of the deposition process. General properties of the deposition and/or the geometry of the substrate surface on which the reaction being modelled occurs may be associated with the behavioral model. A set of material-specific behavioral parameters for one or more types of deposition behavior to be applied to a depositable material in at least one deposition process in the process sequence may be associated with the behavioral model.

A voxel is a unit of graphic information that defines a point in three-dimensional space including, in a Cartesian representation, x, y, and z coordinates. In additional to its coordinates, a voxel may include other information such as the type of material that occupies the space of the voxel.

Each voxel may be represented as a cube, a sphere, or other geometric object of the same size. Various operations performed by process simulation models described herein are performed on voxels (or pixels when using two-dimensional models).

In some implementations, a process simulation models described herein employ fill elements to represent material deposited during a deposition process. The fill elements may have various shapes and sizes depending on the type of process that is being simulated. Examples in two-dimensional process simulation models include circles and ellipses. Examples in three-dimensional process simulation models include spheres and ellipsoids. In some embodiments, the size of a fill element is determined by a local deposition rate determined by a deposition process model. In some embodiments, the size of a fill element varies a function of substrate surface (interface) geometry.

As used herein, a vertical direction is a direction that points substantially away from or into a substrate. In various embodiments, the vertical direction is substantially normal to a plane of the substrate surface (e.g., a flat wafer’s surface). In the context of a substrate surface, a vertical direction generally equates to the “z” direction. The minimum vertical position on a substrate profile or interface is sometimes referred to as Zmin. In the case of a substrate surface having recessed features, Zmin is the position of the bottom of the deepest feature in the substrate.

A lateral direction is a direction that is substantially perpendicular to the vertical direction. In many cases, a lateral direction is substantially parallel to the plane of the substrate surface (e.g., a flat wafer’s surface); two orthogonal lateral directions are sometimes referred to as the “x” and “y” directions.

### Electrofill Applications

Various aspects of this disclosure pertain to computational processes and models for predicting the behavior of electrofill processes such as electrodeposition of metal or other conductive material from an electroplating solution onto a substrate or a portion of a substrate such as a portion having recessed features or protruding features. The computational processes and models may predict fill profiles in and/or around substrate features. The computational processes and models may predict fill profile evolution over time, such as over multiple time steps.

Various aspects of this disclosure pertain to computational processes and models for predicting electroplating behavior in or on partially fabricated integrated circuits, which may be disposed on a substrate surface such as a semiconductor wafer, e.g., a silicon wafer.

The substrate on which a metal or other conductive material may be electrodeposited may have an exposed surface that contains a dielectric material (e.g., silicon oxide, silicon nitride, silicon oxynitride, etc.), a semiconductor, and/or a conductor.

In some cases, the substrate in which the computationally predicted electrodeposition occurs contains recessed features that are holes (e.g., cylindrical holes) or trenches. In certain embodiments, the substrate in which the computationally predicted electrodeposition occurs contains recessed features having a minimum width, diameter, or other opening size at about 10 micrometers or smaller, or about 1 micrometer or smaller, or about 100 micrometers or smaller. In certain embodiments, the substrate in which the computationally predicted electrodeposition occurs contains recessed features having an aspect ratio of about 5 or greater, or about 10 or greater.

Various aspects of this disclosure pertain to computational processes and models for predicting the behavior of electrofill of a metal such as cobalt, copper, nickel, tin, gold, silver, manganese, chromium, molybdenum, iridium, rhenium, palladium, platinum, or combinations of any two or more of these. In some cases, the metal salts in the electroplating solution are chosen to electroplate an alloy of Co and W, an alloy of Ni and W, an alloy of Co and Mo, or an alloy of Ni and Mo.

Various aspects of this disclosure pertain to computational processes and models for predicting the behavior of electrofill in electronic device fabrication applications such as back end of line processing, middle of line processing, and front end of line processing. In some embodiments, a process or model may predict electrofill in a damascene application. In some embodiments, a process or model may predict electrofill in a through silicon via (TSV) application. In some embodiments, a process or model may predict electrofill in a wafer level packaging (WLP) application. In some embodiments, a process or model may predict electrofill in a three-dimensional fabrication application. 3D applications may employ multiple wafers or dies stacked vertically. In some embodiments, a process or model may predict electrofill in a plug application.

Some modeled applications are TSV applications including micro TSV applications. A TSV is a via for an electrical connection passing completely through a semiconductor work piece, such as a silicon wafer or die. A typical TSV process involves forming TSV holes and depositing a conformal diffusion barrier and conductive seed layers on a substrate, followed by filling of the TSV holes with a metal. TSV holes typically have high aspect ratios which makes void-free deposition of copper into such structures a challenging task. TSVs may have aspect ratios of about 4:1 and greater, such as about 10:1 and greater, and even about 20:1 and greater (e.g., reaching about 30:1), with widths at opening of about 0.1 µm or greater, such as about 5 µm or greater, and depths of about 5 µm or greater, such as about 50 µm or greater, and about 100 µm or greater. Examples of TSVs include 5×50 µm and 10×100 µm features.

A micro TSV is a TSV forming an interconnect spanning the thickness of a wafer or integrated circuit, electrically connecting one side of the structure to the other side of the structure. In some embodiments, a micro TSV interconnect electrically connects devices on different sides of a wafer or integrated circuit. As examples, the connected devices may be switches (e.g., transistors) or memory cells. In some applications, two sides of a wafer or integrated circuit have the same type of device (e.g., a transistor or memory cell). In some applications, one side of a wafer or integrated circuit has one type of device while the other side has a different type of device (e.g., transistors on one side of the device and memory cells on a different side of the device). Electrical connection between devices on the two sides of the wafer or integrated circuit may be made by an interconnect spanning the thickness of the wafer or integrated circuit.

In some cases, micro TSVs are used to provide lines for providing chip-level power from one side of a wafer or integrated circuit to the other side. In some cases, micro TSVs are used in integration schemes employing particularly small switches such as 3 nm devices or “gate all around” transistors such as FETs.

The geometric dimensions of micro TSVs are often smaller than those of conventional TSVs. In some embodiments, a micro TSV interconnect has a depth of about 1000 nm to about 2000 nm. In some cases, a micro TSV interconnect has an opening diameter or width of about 50 nm to about 150 nm. As examples, aspect ratios may be between about 5 and about 50.

Some applications form device contacts and are sometimes referred to as middle of line (MOL) or “metal 0” applications. These provide involve electrical connections directly to devices such as transistors or memory cells. As examples, the depth of the features in middle of line applications may be about 50 nm to about 500 nm, or about 100 nm to about 200 nm. In some cases, the opening width or diameter of the features in middle of line applications is about 5 nm to about 20 nm, or about 7 nm to about 10 nm. As examples, aspect ratios may be between about 2 and about 100.

In certain embodiments, 3D NAND devices have tungsten replaced with an electrodeposited metal such cobalt, nickel, and/or an alloy of either. In some cases, the non-W metal fills word lines. In some cases, the non-W metal electrofills 3D NAND contacts. These contacts may have dimensions comparable to large TSVs. The word lines may take the form of large plates, deposited at various levels.

The contact metal may be formed by removal of Si₃N₄ followed by electrofill with metal through a slit which is etched through an ONON stack. Examples of fabrication flows for fabricating 3D NAND structures with vapor deposited tungsten or other metal are described in PCT Patent Application No. PCT/US2020/013693, filed Jan. 15, 2020; and U.S. Pat. Application Publication No. 20180144977, published May 24, 2018, each of which is incorporated herein by reference in its entirety.

In some embodiments, a computational process or model for predicting the behavior of electrofill is configured to predict electrochemical plating of Co replaced MOL W fill in sub 7 nm node due to good bottom-up gap fill capability. In some embodiments, a computational process or model for predicting the behavior of electrofill is configured to predict electrochemical plating of Cu in a BEOL damascene process.

In some embodiments, electrofilled Ni, Co, or alloys of either are used to fabricate transistor gates.

### Electroplating Process and Mechanism (Bottom-Up Fill)

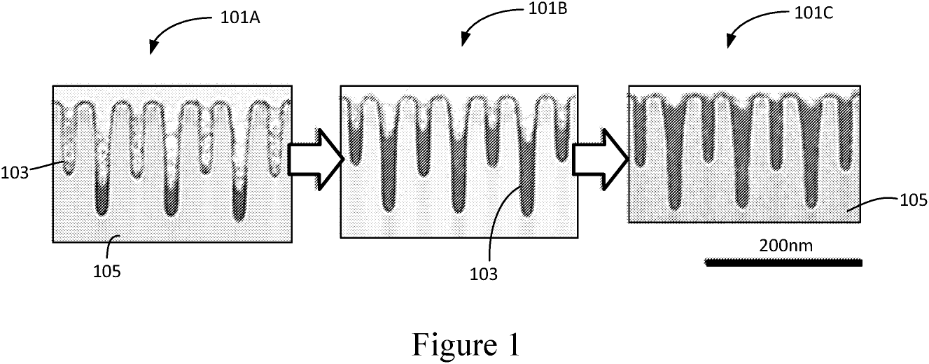

FIG. 1 depicts a cross-sectional profile of three stages 101A, 101B, and 101C of a bottom-up electrofill process in recessed features 103 of a substrate 105. The electrofilled metal is shown as dark regions, initially only in the bottom of features 103 (101A), then extending midway up the feature (101B) without substantially forming on the sidewalls or field regions, and ultimately to the top of the features (101C).

In a bottom-up fill process, a recessed feature on a plating surface tends to be plated with metal from the bottom to the top of the feature. Bottom-up fill may not be a conformal deposition process. Bottom-up fill can occur under conditions that promote relatively high deposition rates deep within a feature relative to lower deposition rates in the field region and/or regions within the feature that are relatively close to the field region. Bottom-up fill may achieve relatively uniform filling and avoid incorporating voids into the features.

While most examples of bottom-up fill presented herein involve a hydrogen ion gradient for cobalt fill, the concept extends to any electrofill system utilizing a concentration gradient (or other gradient caused by or affecting mass transfer or kinetics along features on a substrate) to promote bottom-up fill. For example, processes and models described herein may apply to any electrofill process utilizing a mechanism in which diffusion or other mass transport is used produce a gradient of some species along the Z direction of a feature.

In some metal deposition processes, a hydrogen ion concentration gradient is established and maintained during bottom-up fill. The mechanism may promote a relatively greater reaction rate deep within the feature due to geometric considerations. For example, for a given volume of electrolyte (i.e., electroplating solution), there is a greater surface area available distant from the field region. Therefore, in relatively deeply recessed regions, the hydrogen ions are consumed more readily and the ratio of cobalt ions to hydrogen ions is greater, deep within the feature than closer to the field region. Because the cobalt deposition reaction and the hydrogen reduction reaction compete, a region where there is relatively less hydrogen ions available to be reduced, produces a greater fill rate of cobalt.

The competition and the current efficiency may be represented by the following expressions:

$${\text{Co}}^{2 +} {}_{\left(\text{aq}\right)} + 2 {\text{e}}^{\text{-}} \to {\text{Co}}_{\left(\text{s}\right)} \text{Vs} . 2 {\text{H}}^{+} + 2 {\text{e}}^{\text{-}} \to {\text{H}}_{2}$$

$$\text{Amount} \text{Co} \text{Deposited} < \text{Current} \text{Density}$$

$$\text{Total} \text{current} = {\text{j}}_{\text{Cobalt}} + {\text{j}}_{\text{hydrogen}}$$

$$\text{Current} \text{efficiency} = {\text{j}}_{\text{Cobalt}} / {\text{j}}_{\text{total}}$$

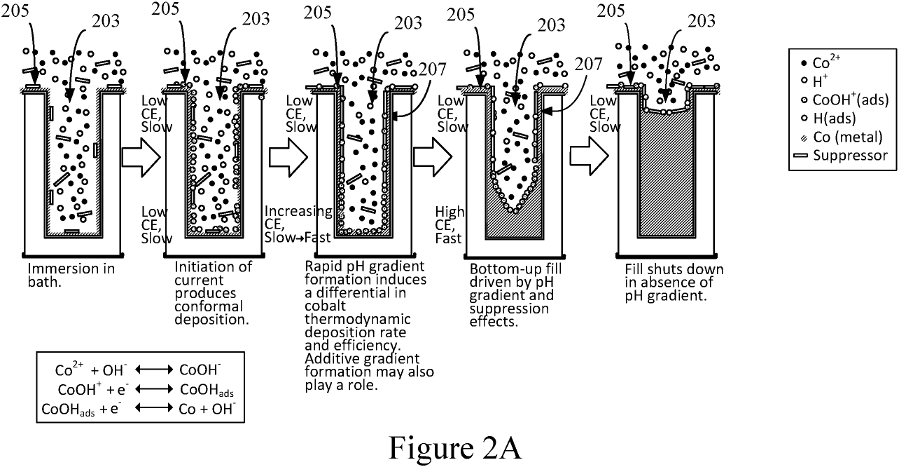

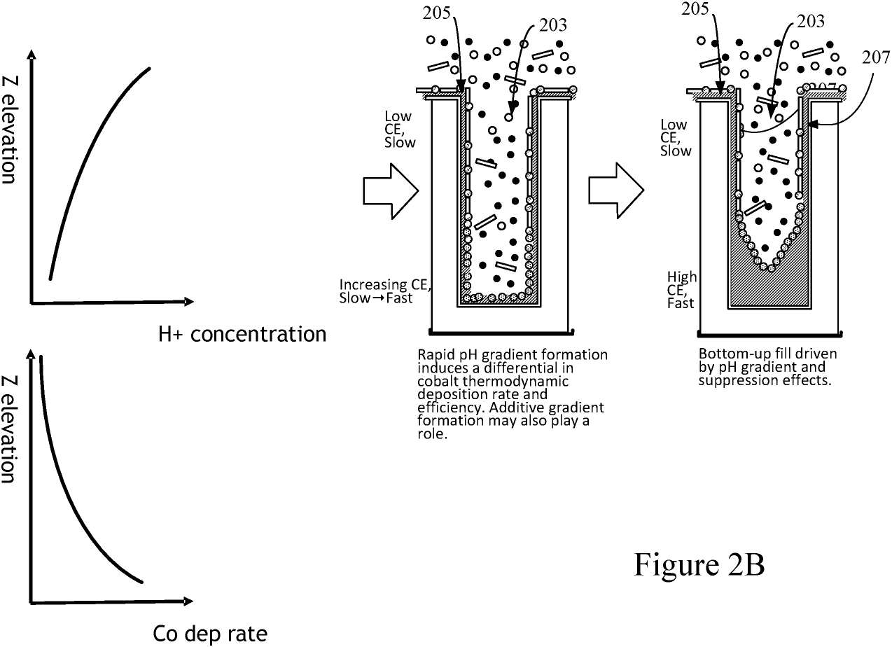

FIGS. 2A and 2B illustrate how solution components may interplay and drive bottom-up fill in a recessed feature 203. The feature field 205 and the upper sidewalls 207 are relatively passivated, and metal electroplating is less efficient due to a relatively high concentration of adsorbed hydrogen ions. Hydrogen ion adsorption lowers the deposition rate of metal on the field due to a competing hydrogen reduction reaction. Overall this leads to slower cobalt deposition 211 at the top of the feature and allows for void free bottom-up fill to be obtained in a range of feature sizes. Examples of a hydrogen ion concentration gradient and a cobalt deposition rate as a function of depth within the features are depicted in FIG. 2B, left panels.

The difference in the rate of electroplating at the feature bottom compared to the rate of electroplating on the field can be increased by an organic additive, the breakdown of an organic additive, or the consumption and/or depletion of hydrogen. To setup void free fill typically a concentration gradient of organic additive coverage and/or hydrogen ion in the feature may be established. This may be accomplished by setting process parameters such as initial solution concentrations (e.g., pH), mass transport (RPM of the substrate being plated) and electroplating current. A wide range of operating conditions can support the hydrogen ion gradient. These may be determined empirically, by modeling the underlying mass transport and other relevant physical conditions, or a combination of both approaches. The gradient is a function of the plating current applied, which drives the consumption of hydrogen ions. As indicated, the gradient forms due to the geometry of the feature, which provides a greater driving force for consumption of hydrogen ions at the base of a feature than in the field regions. In certain embodiments, the starting composition of the electroplating bath has a hydrogen ion concentration of about 0.00001 to 6.4 M.

While some of the discussion herein concerns electrodeposition models in which a gradient of hydrogen ions drives bottom-up fill, the electrodeposition models may account for different or additional mass transfer or gradient driven electrofill processes such as processes employing suppressor gradients within features. In general, models may be designed or configured to account for any mass transfer or diffusion-based process that produces a concentration gradient on the surface along with depth of features to be electrofilled and results in a bottom-up fill profile.

In certain embodiments, the electroplating solution contains, in addition to cobalt salt, a suppressor. In some implementations, the electroplating solution contains a suppressor as the only additive, with no accelerator or leveler. In some implementations, the electroplating solution contains a suppressor along with an accelerator and optionally with a leveler. In some implementations, the electroplating solution contains a suppressor along with a leveler.

In general, suppressing molecules or “suppressors” are molecules that make metal ions reduce less readily onto the substrate. One mechanism by which this may occur is through chemisorption of a molecule on the substrate surface which either sterically hinders the approach of metal ions or occupies reaction sites on the substrate. During the electroplating process, the chosen suppressor interacts with both the unplated substrate surface (e.g., a seed layer) and the partially plated metal film.

Suppressors (either alone or in combination with other electroplating solution additives) are surface-kinetic polarizing compounds that induce a significant increase in the voltage drop across the substrate-electrolyte interface. In some cases, a halide ion acts as a chemisorbed-bridge between the suppressor molecules and the substrate surface. The suppressor both (1) increases the local polarization of the substrate surface at regions where the suppressor is present relative to regions where the suppressor is absent (or present at a relatively lower concentration), and (2) increases the polarization of the substrate surface generally. The increased polarization (local and/or general) corresponds to increased resistivity/impedance and therefore slower plating at a particular applied potential.

Suppressors may be relatively large molecules, and in some instances they are polymeric (e.g., polyethylene oxide (PEO), polypropylene oxide (PPO), polyethylene glycol (PEG), polypropylene glycol (PPG), other general polyalkylene glycol (PAG) polymers, copolymers (including block copolymers) of any of these, and the like). These polymers and copolymers may be further functionalized, with the functional groups that may improve solubility or interaction with the substrate. Some examples of functionalized suppressors include polyethylene oxides and polypropylene oxides with sulfur and/or nitrogen-containing functional groups. The suppressors can have linear chain structures or branch structures or both. A particular class of suppressor molecules includes the organic chemisorption corrosion inhibitors. Suppressor molecules with various molecular weights may co-exist in a suppressor solution.

Due in part to suppressors’ large size, the diffusion of these compounds into a recessed feature can be relatively slow compared to other electroplating solution components.

In some cases, suppressors are not significantly incorporated into the deposited film, though they may slowly degrade over time by electrolysis or chemical decomposition in the electroplating solution.

Examples of suppressors include but are not limited to carboxymethylcellulose; nonylphenolpolyglycol ether; polyethylene glycoldimethyl ether; octandiolbis (polyalkylene glycol ether); octanol polyalkylene glycol ether; oleic acid polyglycol ester; polyethylene propylene glycol; polyethylene glycol; polyethyleneimine; polyethylene glycoldimethyl ether; polyoxypropylene glycol; polypropylene glycol; polyvinyl alcohol; stearic acid polyglycol ester; stearyl alcohol polyglycol ether; polyethylene oxide; ethylene oxide — propylene oxide copolymers; butyl alcohol — ethylene oxide — propylene oxide copolymers; 2-mercapto-5-benzimidazolesulfonic acid; 2-mercaptobenzimidazole (MBI); benzotriazole. In certain embodiments, any one or more of these suppressors may be provided in any of the electroplating solutions disclosed herein in concentrations of about 1-10,000 ppm.

Embodiments involving deposition of certain metals such as copper may employ electroplating solutions having suppressors and accelerators. In some applications, an electrofill model accounts for an accelerator that is included in the electroplating solution. Uncompensated accelerator may accumulate preferentially at the bottom of features and assist in catalyzing metal deposition to support bottom-up fill.

Accelerator molecules can make metal ions reduce more readily onto the substrate relative to a suppressed surface, e.g., a surface having suppressor species attached. It is believed that accelerators (acting either alone or in combination with other electroplating solution additives) locally reduce the polarization effect associated with the presence of suppressors, and thereby locally increase the electrodeposition rate. Accelerator molecules may be used based in part on their ability to sustain higher rates of plating in areas where these high rates begin (vis-à-vis area where suppressor dominates the polarization characteristic).

Electrochemically, accelerators decrease in the magnitude of polarization required to deposit metal onto a suppressed substrate. Since suppressor molecules are more inhibiting than accelerators, one possible mechanism of action of suppressors involves competition with accelerators for binding sites, resulting in higher current densities in those area in which suppressor is supplanted by accelerator.

The reduced polarization effect is most pronounced in regions of the substrate surface where the accelerator is most concentrated (i.e., the polarization is reduced as a function of the local surface concentration of adsorbed accelerator or the ratio of accelerator to suppressor). Although the accelerator may become strongly adsorbed to the substrate surface and may be generally laterally-surface immobile as a result of the plating reactions, in some embodiments, the accelerator is not significantly incorporated into the film. In such cases, the accelerator may remain on the surface as metal is deposited. In some cases, as a recess is filled, the local accelerator concentration increases on the surface within the recess. Accelerators tend to be smaller molecules and exhibit faster diffusion into recessed features, as compared to suppressors.

Examples of accelerators include but are not limited to N,N-dimethyl-dithiocarbamic acid (-3-sulfopropyl)ester; 3-mercapto-propylsulfonic acid-(3-sulfurpropyl) ester; 3-mercapto-propylsulfonic acid sodium salt; carbonic acid-dithio-o-ethylester-s-ester with 3-mercapto-1-propane sulfonic acid potassium salt; bis-sulfopropyl disulfide; 3-(benzothiazolyl-s-thio)propyl sulfonic acid sodium salt; pyridinium propyl sulfobetaine; 1-sodium-3-mercaptopropane-1-sulfonate; N,N-dimethyl-dithiocarbamic acid-(3-sulfoethyl)ester; 3-mercapto-ethyl propylsulfonic acid (3-sulfoethyl)ester; 3-mercapto-ethylsulfonic acid sodium salt; carbonic acid-dithio-o-ethyl ester — s —ester, pyridinium ethyl sulfobetaine; and thiourea. In certain embodiments, any of these accelerators may be present in an electroplating solution at a concentration of about 1-10,000 ppm.

### Model of Deposition Rate (Electrofill)

In certain embodiments, a computational model or process for predicting the behavior of a deposition process accounts for physical and/or chemical variations in the deposition process at different locations (voxels) on a substrate surface interface including one or more geometric features such as a recess or protrusion.

In certain embodiments, a computational model or process for predicting the behavior of a deposition process accounts for a chemical potential gradient such as may be caused by or impacted by a concentration gradient along one or more features or feature components in the interface of a substrate where deposition occurs. In some cases, a chemical potential gradient is modeled by a substrate or feature interface geometry. For example, the depth, height, width, aspect ratio, curvature, and/or other geometric aspect of a voxel may impact a computational model’s or process’ prediction of a local deposition rate.

In certain embodiments, a computational model or process for predicting the behavior of a deposition process employs one or more adjustable parameters that may be fixed ahead of a run of the model. In some cases, a computational model or process for predicting the behavior of a deposition process employs fixed parameters representing physical or chemical aspects of deposition such as a baseline deposition rate, and/or a characteristic diffusion constant of length of one or more species in the deposition medium. In some implementations, a computational model or process employs at least two process-dependent adjustable parameters including a baseline deposition rate or kinetic parameter and a characteristic diffusion length of one or more species in a deposition medium.

In certain embodiments, a computational model or process for predicting the behavior of a deposition process employs one or more parameters that varies as a function of voxel location on the substrate interface. These one or more parameters may serve as independent variables. In certain embodiments, a computational model or process for predicting the behavior of a deposition process employs a single adjustable parameter that varies as a function of position in a feature (e.g., the vertical distance within a recessed feature).

In certain embodiments, a model or process is configured to calculate a local deposition rate using a relationship that reflects the gradient progression of hydrogen or other species in the vertical direction within features. In some implementations, a model or process is configured to calculate a local deposition rate using an exponential relationship in which vertical distance from a reference position such as a deepest feature depth (Zmin) on the substrate interface (or vertical distance from some other reference point on a substrate) is provided as a negative argument in an exponential function. In some cases, the local deposition rate is a function of a negative exponential of a relationship including a vertical difference between the position under consideration (a voxel) and a reference position such as the minimum Z value. Zmin may be determined across all the features considered in the modeling run. Because the calculated value is a negative exponential, the deposition rate will be greater at deeper feature positions. In other words, the deposition rate will be greater deep within features than close to the surface of the features (e.g., a field region on the substrate). In some embodiments, the difference between position under consideration and the minimum distance is scaled by a mass transport parameter such as a diffusion parameter.

The negative exponential expression may correspond to a deposition rate of the metal that is in inverse proportion to the concentration of the hydrogen ion in the solution. In some instances, the distribution of hydrogen ion exponentially decreases with depth (negative Z direction) in a recessed feature. In contrast, the hydrogen ion concentration on the wafer surface may remain relatively constant because, in some physical processes, new solution is continuously added via convection. As a result, a concentration gap always exists between top of the feature (wafer surface) and the bottom of the recessed feature. Hydrogen ions may continually diffuse from top to bottom due to the gap and keep the system stable.

In certain embodiments, a rate expression employed in a computational model or process for predicting electrofill or other deposition in recessed features is given by:

$$R a t e \left(Z\right) = t h k ∗ e x p \left(- 1 ∗ \left(Z - Z m i n\right) / D\right)$$

In this expression, Rate(Z) is the local deposition rate a particular feature depth on the substrate, Z is the vertical position of a voxel under consideration, Zmin is the lowest elevation vertical position in the interface of substrate on which deposition is being modeled, D is a diffusion length or other mass transfer characteristic associated with one or more species influencing the deposition reaction, and thk is a baseline rate value for the deposition reaction. In some embodiments, thk is a maximum deposition rate over all interface positions for a given electrofill process.

Both Z and Zmin are positive in this expression. Since Z is always larger or equal to Zmin, the local deposition Rate (Z) will have a maximum value of thk when Z=Zmin. This indicates that the local deposition rates are largest at feature bottoms. As Z increases (e.g., such as at the bottom of a filling feature), the local deposition rate will potentially decrease (with a decay corresponding to diffusion length D). However, the minimum of the local deposition rate will always be larger than 0, indicating that although the deposition rate at the feature top is small, it is still larger than 0.

As described above, the hydrogen ion concentration may have an exponential distribution along a feature in the Z direction, which may be the root cause for difference of deposition rate between feature’s top and bottom. The parameter D represents the hydrogen ion’s concentration decay length. It may also represent the deposition rate decay length since deposition rate is in inverse proportion to the hydrogen ion concentration.

In certain implementations, the thk, and D parameters are adjustable depending upon considerations such as the electroplating solution chemistry, and the reaction process window considerations such as the metal being deposited, characteristics of the conductive seed layer on which the metal is deposited, the electroplating solution temperature, the local current density, the exchange current density, and the like.

Various considerations may be employed in choosing the model parameters. In some cases, the parameter values are determined by an automated process and/or by conducting particular experiments to generate these parameters. The parameter thk may describe the maximum deposition rate in the substrate. In physical electrofill processes, larger values of thk may be linked with higher local current density and/or other process parameters. D describes the decay length of the deposition rate from a feature’s bottom to top. It can be linked with the electroplating solution’s pH (corresponding to hydrogen ion concentration). A larger value of D may indicate that there is not a large concentration difference between top and bottom of a feature. This may, in turn, indicate that the hydrogen ion concentration of the solution is low.

The value of D can also be linked with the metal being deposited. The current efficiency may be different for different metals. For example, cobalt may exhibit better bottom-up fill behavior than copper. This suggests that a model of cobalt deposition may employ a smaller D value to make the deposition rate difference much larger between a feature’s top and bottom. Other process parameters such as the temperature, may be considered according to their impact on the deposition rate. For example, if higher temperature increases the deposition rate, then a larger thk may be needed. Also, if higher temperature decreases the deposition rate difference between a feature’s top and bottom, then a larger D may be needed.

### Use of Model to Predict Deposition Characteristics

In certain embodiments, the behavioral model is designed or configured to computationally execute the following operations:

1. Find an initial interface where deposition will occur. The interface may be a substrate surface having recessed and/or protruding features represented in two or three dimensions. In the case of an electrodeposition process, this interface may be the boundary between a conductive seed layer and the surrounding environment such as a deposition medium. In the case of vapor deposition method, the interface may be the boundary between substrate surface, including small features, and the surrounding environment (e.g., the vapor deposition chamber environment). In some cases, the interface may include features with a stepped profile and/or various degrees of curvature. In certain embodiments, to find the interface, a computational process may detect all the non-substrate voxels which neighbor substrate voxels (e.g., voxels at locations of the substrate’s seed/metal layer). In some instances, an initial interface is estimated based on one or more parameters, such as metrology parameters. For example, the interface may be estimated as the boundary where solid and free space meet in a cross-sectional micrograph. The initial interface may be determined computationally (e.g., from image analysis of a micrograph) or manually by a user. If the interface is input by a user, the computational model may be configured to receive input defining the initial interface where deposition will occur. For example, the input may be from a user, from an input file, etc.

2. Determine a deposition rate at each of multiple points (voxels) on the interface. The deposition rate may differ as result of feature geometry and/or the chemistry and/or physics of the deposition process. The geometry may account for local geometric feature properties such as feature depth or height, feature curvature, feature aspect ratio, and the like. In some implementations, the geometric properties used to determine local deposition rate include only feature depth. In some implementations, the geometric properties used to determine local deposition rate include only local feature curvature. The chemistry and/or physics of the deposition process may account for diffusion of one or more species in a deposition medium, kinetics of a surface reaction, convection in the deposition medium, and the like. In some implementations, the chemistry and/or physics properties used to determine local deposition rate include only diffusion and/or a baseline reaction rate in the deposition medium and/or in the substrate on which deposition occurs.

3. Adjust the feature surface position at one or more locations of the interface, resulting in a new interface. For example, the adjustment may be made, as needed, to each of the multiple points on the interface where the deposition rate was determined in 2. The adjustment may scale in at least one dimension with the magnitude of the deposition rates determined in 2. In certain embodiments, a geometric adjustment is application of a fill element such as an ellipsoid or circle at an interface location where the deposition rate is determined. The dimensions of the geometric elements may scale with deposition rates. For example, the diameters or axes of geometric objects are proportional to the magnitudes of the deposition rates.

4. To the extent not fully accomplished in 3, the process may define a new interface where deposition will continue to occur. In certain embodiments, this involves smoothing or otherwise adjusting a profile created by the edges of fill elements.

5. Iteratively repeat operations 2-4, with each iteration corresponding to time evolution. The process may end when the amount of deposition and/or the representative time elapsed passes a threshold. In certain embodiments, the process executes over at least five iterations, or at least about ten iterations. The iteration number can be determined by, for example, the ratio of total thickness of the metal that should be deposited to the thickness deposited at each iteration. Additionally, for certain fill processes, the endpoint is the point when the features are fully filled. For certain fill processes, the endpoint is the point when some overburden is formed. So, in a simulation of electrofill, the number of iterations may be selected to make the structure fully filled from bottom to top or to make a defined amount of overburden.

The iteration number may be chosen so that amount of material added in a given iteration is not so large that it masks effects of feature geometry. In some cases, the simulation will produce no difference when using a small value of thk and a large iteration number versus a large value of thk and a small iteration number. However, due to the material replace method in the simulation, a larger value of thk may require a much larger run time (increase by n²), while a larger number of iterations only increase the run time by n. So, from a run time perspective, a small value of thk and a large iteration number may be used.

In some implementations, a rate expression employs a relatively small value of thk, e.g., a threshold, to simulate the electrofill process. In certain embodiments, the value of thk, as applied to the geometric object, is no greater than about 0.2 times the depth or height of a feature to be filled. In certain embodiments, the value of thk is no greater than about 0.1 times the depth or height of a feature to be filled.

In certain embodiments, the deposition amount at a position Z is constrained to be smaller than or equal to half the critical dimension at Z. In certain embodiments, this constraint applies to reentrant recessed features. In certain embodiments, an upper limit value of thk is given by a value that is about equal to TCD/2* exp((Zmax-Zmin)/D), where TCD is the upper critical dimension of a feature (e.g., the smallest upper critical dimension of all features on a substrate being modelled).

In certain embodiments, a behavioral deposition model is applicable in only certain geometric or physical realms. For example, in some implementations, an electofill model is applicable only in electroplating cells employing electroplating solutions and operating conditions configured to provide bottom-up fill. In some implementations, an electofill model is applicable only in substrates having recesses having aspect ratios, on average, of at least about 2:1.

### Electrofill Computational Process Flow

In some embodiments, a computational process for predicting electroplating behavior employs the following operations:
▪ Find Seed/environment interface;
▪ Find Z min;
▪ Calculate deposit rate;
▪ Sweep and mark deposit area;
. Material replace;
▪ Looping

In the sweep and mark operations, the computational process merely sweeps over the interface and marks the points where the modeled deposition will occur. In the material replace operation, the process replaces some region (area in two-dimensional simulations and volume in three-dimensional simulations) occupied by electrolyte at the marked positions with deposited metal.

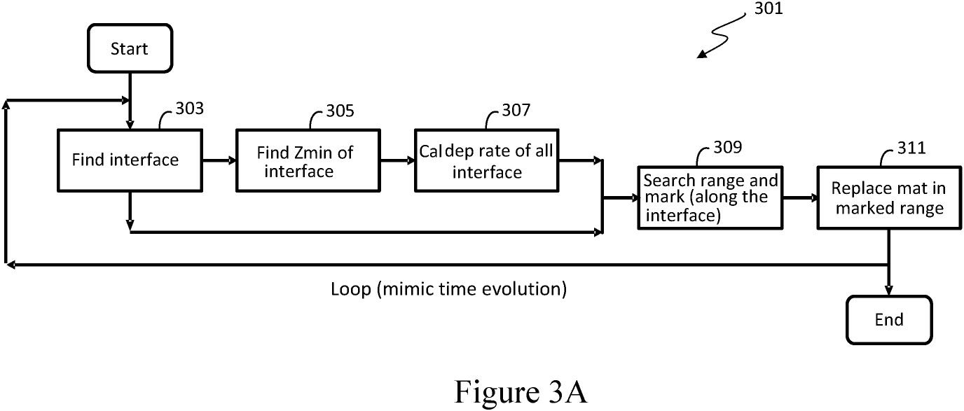

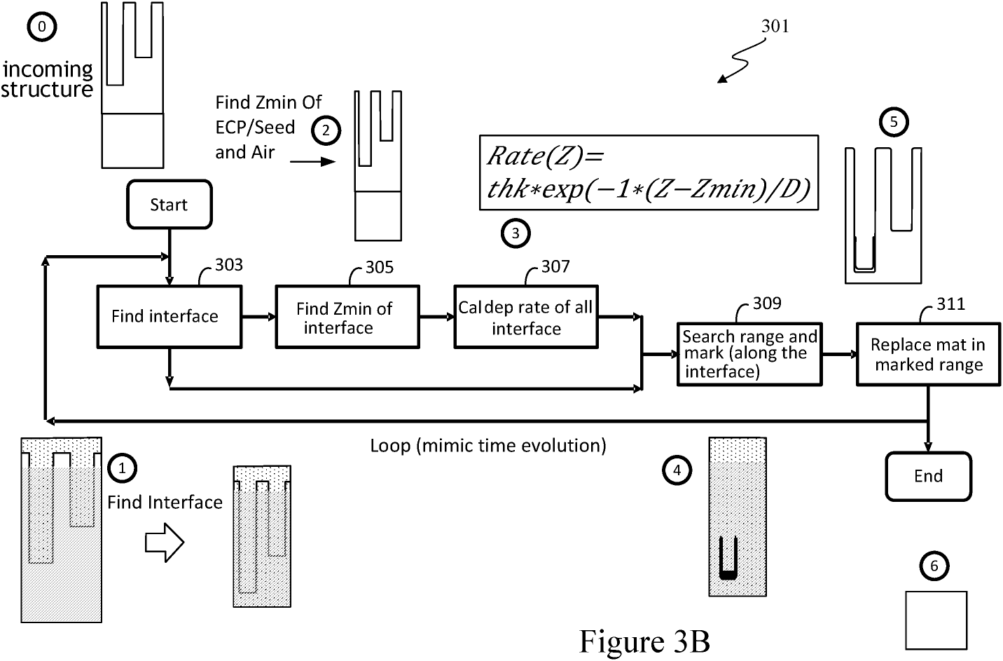

An example computational process flow is depicted in FIG. 3A. As illustrated, a process 301 begins by finding an interface where deposition may occur. See block 303. In the case of electrofill, this is typically an outer exposed surface of a conductive material that, during the start of an electrodeposition process, contacts an electroplating solution during deposition. In certain embodiments, the interface at the start of the process is an exposed surface of a conductive seed layer, such as a seed layer formed using physical vapor deposition, chemical vapor deposition, or atomic layer deposition.

Next, the process locates the minimum elevation of the interface, Zmin. See block 305. This is the lowest point of all recessed features being modeled. Low is defined in a direction perpendicular to a plane on the active surface of the substrate on which electrodeposition occurs. Recessed features may be characterized by negative elevation values with respect to the plane of the wafer surface. Zmin is the most negative value of this across all features in the substrate. In alternative embodiments, a reference point other than Zmin is chosen.

Next, the process computationally calculates the deposition rate at each of a plurality of positions (voxels) defined on the interface. See block 307. The number and/or density of positions may vary depending on various considerations such as the amount by which the deposition rate is expected vary over a particular distance, available computational resources, etc. As indicated in the description of a computational model, the deposition rate may be determined with reference to a defined point on the substrate or interface. In the depicted process flow, that reference point is Zmin. An expression for calculating local electrodeposition rate may have any one or more of the characteristics described herein. For example, it may employ an exponential function of an interface position dependent variable. Note that an expression for calculating local deposition rate may have one or more process-specific parameters such as a baseline deposition rate and/or a characteristic mass transport parameter such as diffusion length. In certain embodiments, a user initially defines process-specific parameters such as thk and/or D.

After the local rates are determined at all positions along the current iteration’s interface, the computational process marks each position on that interface with an indication of the deposition rate. See block 309. Then, the interface is replaced by applying a mat (e.g., a layer comprising voxels and disposed on an interface) or other geometric representation of the electrodepositing layer that varies as a function of the marked deposition rates. See block 311. In certain embodiments, the mat is generated by applying a sphere or other geometric object at each position. In some cases, a sphere’s radius is a function of the calculated local deposition rate. In certain embodiments, the sphere’s radius is proportional to the local rate.

In certain embodiments, the spheres are applied so that a portion of (e.g., one half) their areas (two-dimensional models) or one half their volumes (three-dimensional models) are inside the surface of the interface (within the solid) and the remaining portion is outside or beyond the surface, extending into area formerly occupied by the electroplating solution. Thus, the portion of the circle or sphere extending outside or beyond the surface represents deposited material.

After the spheres or other manifestations of the mat are applied at all the positions for which the reaction rate or deposition rate is calculated, the process may perform a check to determine whether the model run is complete. This may involve determining, for example, whether the features have been completely filled, or there is some minimum thickness of fill above the field region, or a sufficient number of iterations have been performed.

Assuming that the computational process is not complete, process control returns to operation 311 and the next iteration begins. After the spheres or other geometric modifications are applied at all the positions for which the deposition rate is calculated, the model recalculates the interface between the solid and the electrolyte solution. This of course accounts for the additional material deposited which is represented by the spheres that have been applied at the various locations where the rate is calculated.

FIG. 3B presents a computational process embodiment mirroring that of FIG. 3A but including more illustrations of the possible implementations of certain process operations. A graphic “0” represents the profile of a substrate structure having features into which cobalt or other metal is to be electroplated by the process being modeled. In some cases, this structure is obtained from metrology performed on a substrate that has undergone processing to the point where it is about to be subjected to the electrodeposition process that is being modeled. A graphic “1” represents a computational process of finding a substrate-deposition solution interface, which is represented by a profile having two recessed features and a field region. This may correspond to operation 303. A graphic “2” represents finding the minimum or lowest position (Zmin) in the interface obtained in “2.” Finding the minimum corresponds to operation 305. A graphic “3” represents calculating the deposition rate at a given position (voxel) on the interface using the local vertical position (Z) of the position. See operation 307. The recited expression is one example of a technique for determining the local deposition rate. A graphic “4” represents operation 309, marking deposition rates along the interface. Finally, a graphic “5” represents operation 311, which involves inserting a geometric modification at the locations where the local rate was calculated.

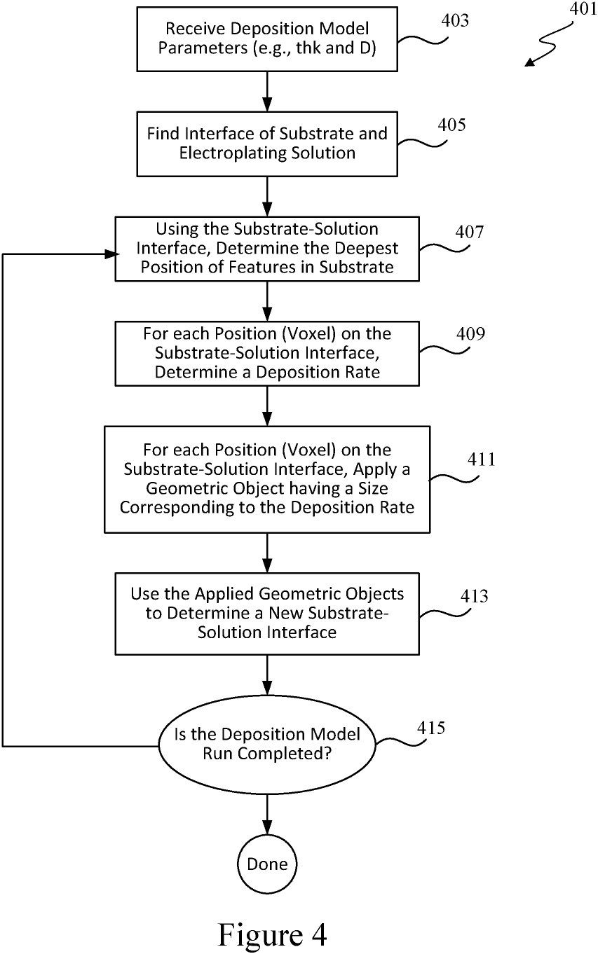

FIG. 4 depicts another computational process embodiment 401. The process begins by receiving parameter values for the deposition model. In the depicted embodiment, these are a baseline or maximum deposition rate and a characteristic diffusion length. See block 403. Next, the process finds an interface of substrate (and particularly feature profiles) and the electroplating solution that will be used as a source of the metal to be deposited. See block 405. Operations 403 and 405 may serve to set up an iterative execution of the model, where each iteration represents a time step or other representation of the deposition process evolution.

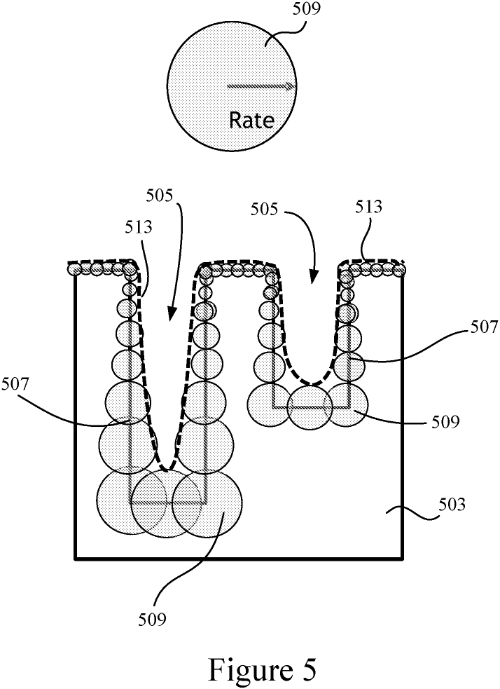

Now, upon entering the time evolution portion of the computational process, the computational system uses the substrate-solution interface from 405 to determine the deepest position of features in the substrate or, alternatively, some other reference position. See block 407. This value of the reference position may be used in determining the local deposition rates in a current iteration. Regardless, the next operation in process 401 determines a local deposition rate at each position (voxel) on the substrate-solution interface. See block 409. Any appropriate deposition rate model, including those described above, may be employed. Then, at each position (voxel) on the substrate-solution interface, the computational process applies a geometric modification having a size corresponding to the deposition rate. See block 411 and, for example, FIG. 5, where a geometric object is applied to the interfacial positions. Next, the computational process uses the applied geometric modifications to determine a new substrate-solution interface. See block 413 and, for example, FIG. 5.

Operations 407, 409, 411, and 413 may be viewed, collectively, as representing the deposition that occurs during a single time step. In each iteration, the substrate-electrolyte interface is recalculated and the Zmin or other reference parameter for determining position-dependent rate is also recalculated.

Because the computational process is iterative, it may end after operation 413 is complete. Hence, the process 401 has a check for completing the process. See decision block 415. Assuming, that the completion criterion has not been met, process control loops back to operation 407, which determines a new reference position (e.g., Zmin) using the new interface. Thereafter, operation 409 determines the deposition rate for each voxel on the new interface, and current iteration proceeds with operations 411 and 413, as described above.

FIG. 5 presents a computational embodiment that may correspond to operation 309 and/or 311 of FIG. 3A and operation 411 of FIG. 4. As depicted, a modeled substrate 503 includes modeled recessed features 505. An initial substrate-solution interface 507 has a series of positions where deposition is calculated. The computational process provides geometric objects 509 to represent deposited material, with the size of the geometric objects depending on the calculated local rate of deposition. In the depicted embodiment, geometric objects 509 are circles having radii that scale with calculated local deposition rate. The process places the appropriately sized geometric at all voxel positions. The resulting region occupied by the newly placed geometric objects 511 may define a new interface. However, as depicted a rough interface defined by placement of the geometric objects 511 may be smoothed with a final interface 513.

The starting cross-sectional profile of the substrate may be obtained by any of various techniques. Such techniques may be experimental, theoretical, and/or computational. In certain embodiments, the starting cross-sectional profile can be obtained by a microscopy technique such as TEM or SEM. In certain embodiments, cross-sectional profiles of the substrate are obtained by wafer splits with different electrodeposition times. This may be appropriate when the model is intended to simulate only a portion of a deposition process.

In certain embodiments, a 2D or 3D representation of the substrate structure is stored in a form of an array having elements corresponding to the locations (voxels) on or in the substrate. Individual elements of the array may have properties such as material characteristics. To find the interface, a computational process may detect all the non-substrate voxels which neighbor substrate voxels (e.g., voxels at locations of the substrate’s seed/metal layer). With the interface determined, the computational process can evaluate all the interface voxels to find the one or more interface voxels having a minimum value of Z and setting this minimum value as Zmin.

In certain embodiments, no surface smoothing algorithm is applied to the spheres or other geometric objects. Therefore, in some cases, the output structure may have 0.5 voxel resolution errors in the thickness. One method to minimize this error is to use smaller voxel resolution which produces a tradeoff with the run time. In certain embodiments, a smoothing algorithm is employed to smooth the new interface produced by applying the spheres or other geometric objects.

The rate parameter, thk, describes a maximum deposition rate at any vertical position in the substrate. In a physical electrochemical deposition process, larger values of thk may be associated with higher local current density, the presence of unsuppressed accelerator, and/or other process conditions that promote overall higher deposition rate.

As indicated, the parameter D may represent the decay length of the deposition rate as a function of the vertical position in or along a feature. The value of D may be with concentration and/or mass transfer of one or more species participating in or hindering the deposition reaction. In certain embodiments, the value of D is linked with the pH value (H⁺ concentration) of the electroplating solution. A larger value of D may correspond to there being a relatively modest concentration difference between the top and bottom of a feature. This may, in turn, indicate that the bulk H⁺ concentration of the solution is relatively low. Also, the D value can be linked with the metal material being deposited due to, for example, the current efficiency being different under the same conditions for one metal versus a different metal. For example, Co may show much more significant bottom-up fill behavior than Cu. This may indicate that for Co simulations, a smaller D value is needed to make the deposition rate difference much larger between top and bottom.

Other parameters, such as the temperature, need to be considered according to its impact on the deposition rate and its loading between top and bottom. For example, if higher temperature can make the deposition much faster, then a larger value of thk will be needed. Also, if higher temperature makes the deposition rate difference become smaller between top and bottom, a larger value of D will be needed.

The above rate expression uses only a simple exponential expression to calculate the deposition rate as a function of the value of Z. In some embodiments, the simulation does not make a distinction based on the density of points (voxels) where rate is calculated on the interface. Because the exponential expression itself is smooth, the generated surface of the metal is theoretically smooth. In certain embodiments, no smoothing operation is applied.

In some embodiments, the density of positions on the interface (voxels where rate is calculated) varies depending on the location on the interface. In some implementations, the density of points may be greater on convex interface surfaces than on flat and/or concave interface surfaces. In some implementations, the density of points may be less on concave interface surfaces than on flat and/or convex interface surfaces.

The density of voxels on the interface may also be related to the value of thk. If the voxel size (voxel resolution) is much smaller than the sphere radius, the new interface produced during an iteration will be relatively smooth. In some implementations, the simulation uses a relatively small resolution (small voxel size) in cases where thk is relatively small. In certain embodiments, the value of thk is at least about 4 times the voxel separation distance, assuming constant voxel separation distance.

Of course, the units of thk and voxel separation distance are different. The value of thk in such embodiments may be determined based on, at least in part, its function as a radius or other dimension in a geometric object applied to the interface during the simulation.

With each iteration, there is an entirely new feature profile, i.e., an entirely new solid-liquid interface, so the points used for calculating deposition rate must be redetermined each iteration. In some implementations, the number of points on the interface and/or the density of points on the interface preserved from iteration to iteration. In some implementations, the number of points and/or the density of points varies from iteration to iteration.

In certain embodiments, the computational instructions are configured to vary, or permit variation of, the parameters thk and/or D with each iteration. The starting parameter value and/or the parameter value variations with iteration may be set or adjusted automatically or manually. In some cases, the parameter value adjustment can be performed independently on any given iteration. Also, the D and/or thk value(s) may be an explicit function of the current iteration number. The rate expression may include iteration number as a parameter value. In certain embodiments, as iterations continue, the value of thk and/or D may vary. Also, the simulation logic can be configured to determine the feature depth in each loop (measure Zmin by a “virtual metrology”). In some implementations, the feature depth can be output as a variable, and this variable can be used in the next iteration to determine the value of thk by setting the value of thk as a function of the feature depth. Any process of varying parameter values during a simulation can be implemented within the electrochemical deposition simulation algorithm.

The modeled electrodeposition process may be used for various purposes. In some embodiments, they are used to modify electrofill process conditions to achieve a better result than predicted by the model. In some embodiments, they are used to modify an incoming interface/profile to achieve a better result than predicted by the model. In the first case, different process conditions may be manifest as different process-dependent variable in the deposition rate expression or model. This may translate to different values of parameters such as thk and D. By executing the process multiple times using different process-dependent parameter values and/or different incoming interface profiles, the overall process can hone in on process conditions or initial geometries that provide a desired electrofill result.

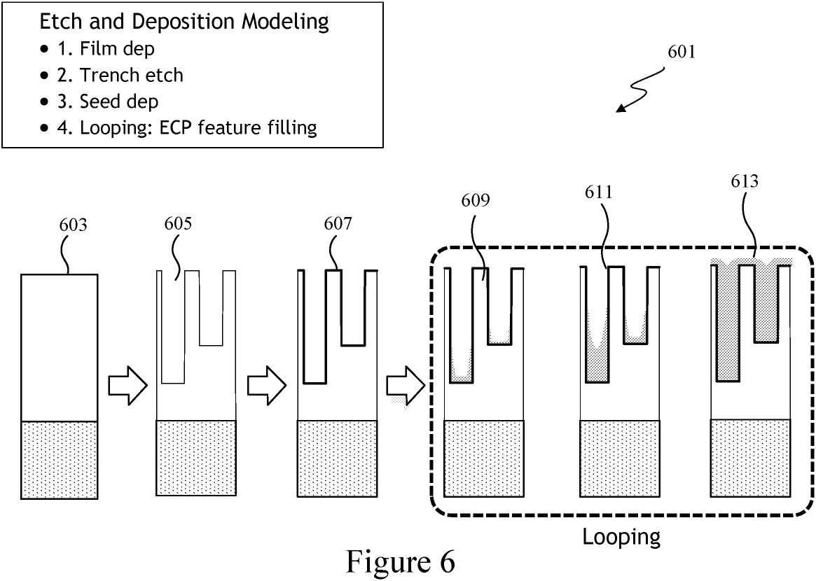

In certain embodiments, the electrodeposition modeling process is coupled with models of one or more other processes upstream or downstream of the electrodeposition modeling. FIG. 6 illustrates a computational process 601 in which an etch model receives, as input, an unetched substrate 603, which may have mask or other lithographic design to define regions of etching. The etch model predicts an etch pattern 605 that an etch process will produce in the substrate 603. The computational process 601 may apply a conductive seed layer that conformally covers the etched substrate as depicted in profile 607. The computational process 601 then predicts the iterative evolution of a bottom-up electrofill process as illustrated in three phases of electrofill: 609, 611, and 613.

### Vapor Deposition Applications

Aspects of this disclosure pertain to computational processes and models for predicting the behavior of vapor deposition processes such as chemical vapor deposition and/or physical vapor deposition of a material from the vapor phase onto a substrate or a portion of a substrate such as a portion having recessed features or protruding features. The computational processes and models may predict deposition profiles in and/or around substrate features. The computational processes and models may predict deposition profile evolution over time, such as over multiple time steps.

Some embodiments of this disclosure pertain to computational processes and models for predicting vapor deposition behavior in or on partially fabricated integrated circuits, which may be disposed on a substrate surface such as a semiconductor wafer, e.g., a silicon wafer.

The substrate on which a material is vapor deposited may have an exposed surface that contains a dielectric material (e.g., silicon oxide, silicon nitride, silicon oxynitride, etc.), a semiconductor, and/or a conductor. The material that is vapor deposited may be a dielectric, a metal, or semiconductor.

In some cases, the substrate in which the computationally predicted vapor deposition occurs contains recessed features that are holes (e.g., polygonal or cylindrical holes) or trenches. In certain embodiments, the substrate in which the computationally predicted vapor deposition occurs contains recessed features having a minimum width, diameter, or other opening size of about 10 micrometers or smaller, or about 1 micrometer or smaller, or about 100 micrometers or smaller. In certain embodiments, the substrate in which the computationally predicted vapor deposition occurs contains recessed features having an aspect ratio of about 5 or greater, or about 10 or greater.

In some applications, the vapor deposition process fills a recess having steps, which may be arranged in a staircase fashion. Such features may be present in partially fabricated memory structures such as 3DNAND elements.

As with the electrochemical deposition method described herein, the vapor deposition method employs a behavioral model to represent the fill of a feature, step-by-step, over multiple time steps or deposition size steps. Additionally, the fill in a given iteration may be represented by curved geometric objects (e.g., circles or ellipses).

However, in certain embodiments, the fill geometric object is an ellipse rather than a sphere, or the object is an ellipsoid in three-dimensional deposition models. The ellipse or ellipsoid is used to represent relatively faster rates of deposition in one or two directions compared to a third direction. For example, for the ellipsoids used in certain embodiments of this disclosure, the deposition rate in the x and/or y directions (lateral directions) is faster than in z direction (vertical direction, into the feature).

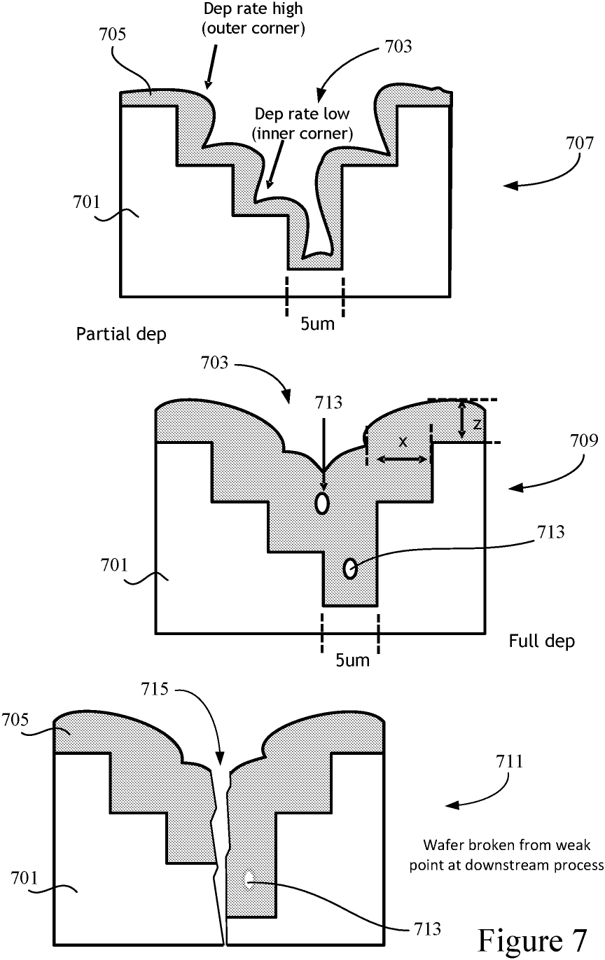

FIG. 7 illustrates an example vapor deposition process for filling a stepped, recessed feature 703 with a fill material 705. Feature 703 is formed in a substrate 701. The dimensions shown in this example are for illustration only.

In the illustration, the process is depicted as a series of three time-evolved snapshots. In a panel 707, the deposition process is in its early phase, during which a relatively small portion of the recess volume is filled. In a panel 709, the deposition process is in a later phase, where all or a relatively high fraction of the recess volume is filled. Finally, as illustrated in a panel 711, a damaging event occurs that causes a crack 715 in the device structure.

As illustrated in deposition sequence panels 707 and 709, the local deposition may have unequal lateral and vertical rates. For example, the lateral deposition rate may be greater than the vertical deposition rate. Alternatively, or in addition, the local deposition rate may be dependent on the local geometry of the feature location where deposition is occurring. For example, the deposition rate may vary with the local curvature of the interface location where deposition occurs. In the illustrated embodiment, the deposition rate is greater in an outer corner than in an inner corner.

As illustrated in panel 709, the local deposition rate variations, coupled with the geometry of the unfilled feature 703, can cause formation of voids 713. One or more of these voids can introduce a weak point that facilitates subsequent formation of a crack 715 in the device structure, as illustrated in panel 711.

### Model of Deposition Rate (Vapor Deposition)

In certain embodiments, a computational model or process for predicting the behavior of a vapor deposition process accounts for local geometric variations at different locations (voxels) on a substrate surface interface in or near a substrate features such as a recess or protrusion.

In certain embodiments, a computational model or process for predicting the behavior of a vapor deposition process employs one or more adjustable parameters that may be fixed ahead of a run of the model. In some cases, a computational model or process for predicting the behavior of a vapor deposition process employs fixed parameters representing physical or chemical aspects of deposition such as a baseline deposition rate and/or a preferential direction of deposition (e.g., lateral over vertical). In some implementations, a computational model or process employs at least two process-dependent adjustable parameters including a baseline deposition rate or kinetic parameter and a directional characteristic of the deposition process (e.g., relative contributions of vertical and lateral components to the deposition).

In certain embodiments, a computational model or process for predicting the behavior of a vapor deposition process employs one or more parameters that varies as a function of voxel location on the substrate interface. These one or more parameters may serve as independent variables. In certain embodiments, a computational model or process for predicting the behavior of a deposition process employs a single adjustable parameter that varies as a function of position in a feature (e.g., the local curvature within or on a feature where deposition occurs).

In some implementations, a model of a vapor deposition process employs an angular dependent deposition rate, where the angle describes the local geometry of a region of an interface where deposition is being modeled. In certain embodiments, a model or process is configured to calculate a local deposition rate using a linear relationship in which local curvature of the substrate interface (or another shape-based geometric parameter) is used as an independent variable. In certain embodiments, the model applies a faster deposition rate on local structures having outside corners (high curvature) than on local structures having inside corners (low curvature).

In certain embodiments, a model of a vapor deposition process employs a direction-dependent deposition rate. In embodiments, the directional dependence applies a different deposition rate in a vertical direction (e.g., substantially normal to the main planar surface of the substrate) than in a lateral direction (e.g., substantially parallel to the main planar surface of the substrate). In some implementations, the model applies a faster deposition rate in one or two lateral directions than in a vertical direction. In some implementations, the ratio of deposition rates in two different directions is fixed regardless of where on the interface deposition is being modeled. In some implementations, the ratio of deposition rates in two different directions may vary as a function of location on the interface and/or the iteration number of an iterative model.

In certain embodiments, a vapor deposition model having one or more properties described in this section is designed or configured to model deposition in features having recesses. In certain embodiments, a vapor deposition model having one or more properties described in this section is designed or configured to model deposition in features having variable angles within a recessed feature. An example is a recessed feature having one or more steps therein.

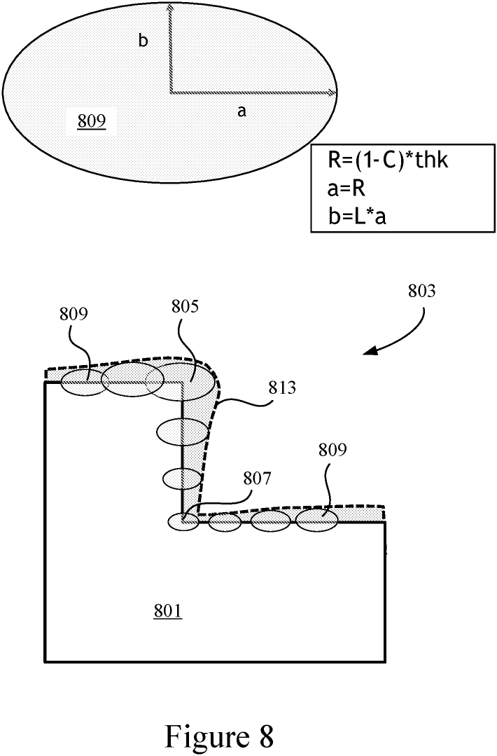

FIG. 8 illustrates a feature being filled in accordance with an example of a vapor deposition simulation (e.g., a simulation of a CVD or ALD process). As illustrated, a substrate 801 has a surface with a portion of a feature 803 on which deposition is occurring. In some embodiments, feature portion 803 is a step in a recessed feature. Feature 803 has two corners, an outward pointing corner 805 and an inward pointing corner 807.

In certain embodiment, the model of vapor deposition is implemented by modifying the positions of a substrate-vapor interface to account for the deposition rate on a position-by-position basis. In some implementations, the positions are modified by applying geometric objects at the interface positions, with the objects sized to reflect the local, position-dependent deposition rates.

The model whose operation is illustrated in FIG. 8 represents deposition by applying ellipsoidal elements 809 at locations on the feature portion where the deposition rate is calculated. In the depicted embodiment, the sizes of ellipsoidal elements 809 are determined by the local deposition rates, which are dependent on the local geometry of the interface where deposition is being modeled. The sizes of the objects may scale with the magnitudes of the local deposition rates. In the depicted embodiment, the shape of ellipsoidal elements 809 represents the relative rates of lateral and vertical deposition. The ratio of these two rates is given by a fixed parameter L.

In certain embodiments, a local rate expression employed in a computational model or process for predicting vapor deposition is given by:

$$R = \left(1 - C\right) \text{*} t h k$$

In this expression, R is the local deposition rate in at least one direction (e.g., one or more lateral directions), C is the local curvature of the substrate-vapor interface where the deposition rate is calculated, and thk is a baseline rate value for the deposition reaction. In some embodiments, thk is a maximum deposition rate at a location of maximum curvature (i.e., C = 0).

As mentioned, in some implementations, the deposition rate is different in different directions. For example, the lateral deposition rate may be greater than the vertical deposition rate. This situation may be addressed by using a scaling factor, which is represented by the parameter L in the depicted embodiment.

The ellipsoidal elements 809 of FIG. 8 have a semi-major axis, a, having a magnitude given by the magnitude of the local rate, R. The ellipsoidal elements 809 also have a semi-minor axis, b, given by a reduced rate in which R is scaled by a factor L. In other words,

$$a \text{=} R$$

$$b \text{=} L \text{*} a$$

In ellipsoidal elements 809, a represents the lateral deposition rate and b represents the vertical deposition rate. In three-dimensional implementations, the values of these parameters may be identical or different in the two lateral dimensions (e.g., x and y, versus z).

In certain implementations, the thk, and L parameters are adjustable depending upon considerations such as the vapor deposition process and/or the deposition apparatus design or configuration.

For example, the parameters thk, and L may be adjustable to meet physical properties of the deposition process being simulated. In some implementations, an experiment with time split partial deposition is conducted. The collected dimension information from this deposition may be employed to decide or calibrate the parameters thk, and L to make a virtual structure match real structure at each step (experimental time split). In certain embodiments, a simulation employs a relatively small value of thk with a relatively large number of iterations because after each iteration (loop), the surface curvature will be changed. If thk is too large, the evolution error may be large.

In certain embodiments, the magnitudes of thk and local feature contours are related. A large value of thk could create ellipsoidal fill elements that would hide local feature variations. In certain embodiments, the value of thk is smaller than the scale of the feature profile. After each iteration (loop), the local surface curvature values of interface will be changed. If thk is too large, the evolution error may be large. In certain embodiments, the value of thk is at least about 4 times as large as the voxel size.

In certain embodiments, a new substrate-vapor interface 813 is determined based upon the edges of ellipsoidal elements 809 opposite the substrate. In certain embodiments, a computational process determines substrate-vapor interface 813 by using a smoothing or profiling routine.

The curvature of a local profile or contour within a feature can be calculated by any of various techniques. Some involve determining the radius of a circle or other curved geometric object having a perimeter that follows a portion of the contour of the profile under consideration. In some embodiments, curvature is provided as a fraction of an area or volume of a curvature-defining geometric object (e.g., a template circle or sphere) overlapping with a substrate when the geometric object is placed over the substrate interface containing the local profile being evaluated.

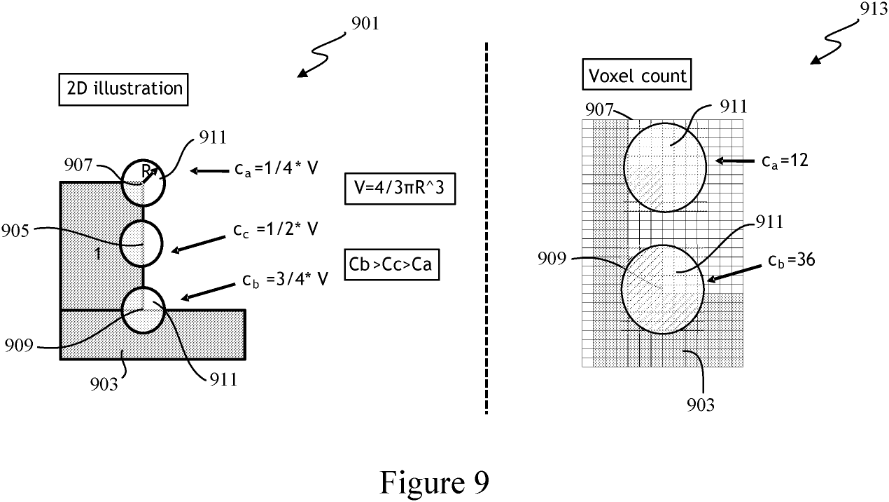

FIG. 9 depicts an embodiment for computationally determining the curvature of a contour at the interface of a substrate and vapor. As depicted in a panel 901, the interface of a substrate 903 has a step profile including a sidewall 905, an outward facing corner. 907, and in inward facing corner 909. Each of these has a different curvature.

Consistent with the deposition rate expression above, the curvature value may be computed such that it has a relatively larger value for inward facing corner 909 than for outward facing corner 905. In such approach, the curvature at inward facing corner 909 may be greater than the curvature at sidewall 905, which may be, in turn, greater than the curvature at outward facing corner. 907. One approach to meeting this constraint is to have the curvature calculated based on the number of voxels on the substrate side of the interface in the region of the contour for which the curvature is being computed. And this is the technique that is depicted in Figure CU.

As illustrated in panel 901, a technique for determining this voxel count involves centering a circle, sphere, or other geometric object 911 over the interface. In the depicted embodiment, the center of a circle or sphere 911 is placed at the point where the curvature is to be calculated. In other words, if the deposition rate, which is a function of curvature, is to be calculated at a position m, circle or sphere 911 should be centered on position m. With the circle or sphere’s center so placed, the number of voxels within the substrate (i.e., within the solid phase side of the interface) that are also within the area of the circle or sphere may be counted. The count is equal to or proportional to the curvature of the contour at position m.

While the embodiment shows a two-dimensional feature and associated curvature-determining circle, the approach applies in either two dimensions or three dimensions. In the case of two dimensions, a circle or ellipse may be used, while in the case of three dimensions, a sphere, ellipsoid, or other volumetric geometric object may be used.

In certain embodiments, the curvature is calculated in a manner than normalizes the curvature to always be less than 1. This may be accomplished by, for example, dividing a subsumed area or volume of the substrate within the curvature-defining circle or sphere 911 by the total volume of the circle or sphere.

An example computational technique is further illustrated in panel 913 which shows the substrate voxels that fall within curvature-defining circle or sphere 911 at corner position 907 and corner position 909. As can be seen, the voxel count meeting these criteria at 907 is 12, while the voxel count meeting these criteria at positions. 909 is 36.

In some embodiments, the size of the spheres used to determine curvature are of the same relative scale as the size of the contours for which curvature is being determined. This avoids swamping the curvature measurement for a particular corner by using spheres that would subsume multiple corners or nearby contours.

In some implementations, the radius of the curvature calculation sphere has a value that is within an order of magnitude of the average contour dimensions of a real feature that is to be filled or covered with vapor deposited material. However, in some cases, the value of the radius of curvature may be large enough to subsume a local profile difference. This may be the case when two local surface points have different curvatures (locally) but show little thickness loading.

### Vapor Deposition Computational Process Flow

In some embodiments, a computational process for simulating a vapor deposition process for filling features on a substrate has the following the operations.

1. Find interface of the substrate and the vapor-containing environment.

2. calculate curvature for each voxel on interface
a. The curvature values, c, may be determined using various methods and optionally normalized by dividing by a characteristic area (circle-based method for two-dimensional simulations) or a characteristic volume (sphere-based method for three-dimensional simulations);
b. The deposition rate varies as a function ofcurvature and may use a rate expression dependent on curvature (and optionally curvature alone). As an example, the rate expression is given by R=(1-C)*thk;
c. This deposition rate in the lateral and vertical directions may be different. For example, the rate in the lateral direction (x,y) may be given by rate (a=R);
d. The vertical deposition rate may be scaled by a vertical/lateral ratio parameter, L. For example, the vertical deposition rate may be given by b=L *a.

3. Along the interface, apply ellipses or ellipsoids having vertical and lateral radii corresponding to the curvature-derived vertical and lateral deposition rates.

4. Reset surface/interface using the applied ellipses or ellipsoids.

5. Repeat operations 1-4 until an end criterion is met.

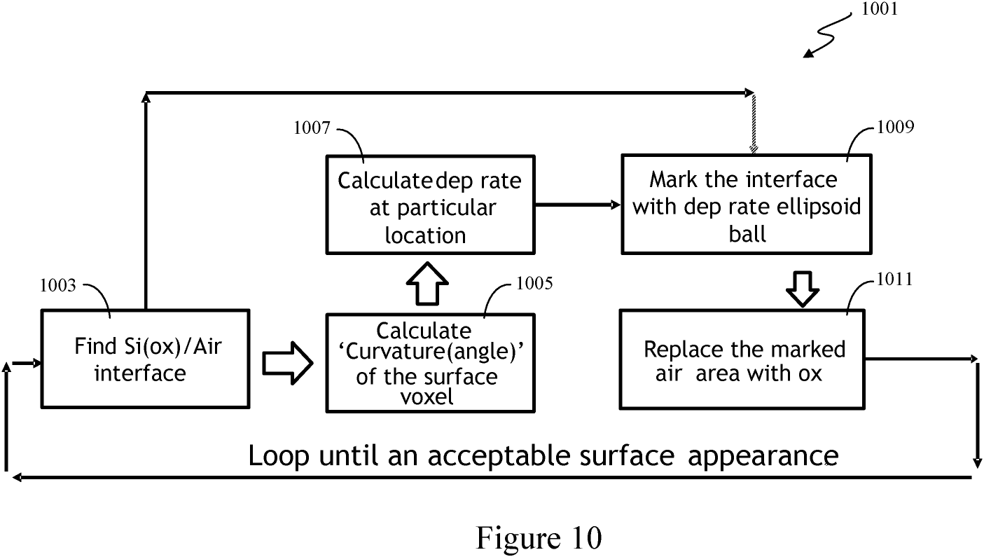

FIG. 10 illustrates an example of a computational process 1001 for determining the time evolving profile of a substrate-vapor interface during a vapor deposition process. Computational process 1001 begins with an operation 1003 that finds a substrate-vapor interface of the features being modeled in the process. In certain embodiments, finding this interface may be performed in a manner similar or identical to that described above with respect to finding a substrate-medium interface for a model of electrofill on a substrate.

Next, as illustrated, compositional process 1001 calculates a curvature angle of a surface voxel under consideration. See block 1005. The curvature may be determined by any of a number of available techniques. Examples of such technique are described above, including the technique illustrated with respect to Figure CU. Operation 1005 is repeated for each of the surface interface voxels where the vapor phase deposition rate is to be determined.

With the local curvature now determined for the relevant surface voxels, the process calculates a local rate at each of these surface voxels. See operation 1007. A model such as that described above may be employed to calculate the local deposition rates in operation 1007. The rates are calculated using the curvatures that were calculated in operation 1005. In certain embodiments, this operation is performed using one or more additional parameters such as a baseline deposition rate, such as a maximum deposition rate, and a scaling element that represents the ratio of lateral to vertical deposition rates for asymmetric deposition.

With the local deposition rates determined at every surface voxel of interest, the process next applies a geometric modification at each of these voxels, and that modification has a magnitude that is determined by the local deposition rate. See operation 1009. As illustrated, the current iteration’s starting substrate-vapor interface is fed into operation 1009 to determine locations for applying the new ellipses or ellipsoidal elements. In certain embodiments, the modification involves application of an ellipse (two-dimensional modeling) or ellipsoidal element (three-dimensional modeling) centered on each voxel where deposition rate was determined. See, for example, the elements 809 in Figure VG. The magnitude of each of the major and minor axes of the ellipse or ellipsoidal volume elements may be determined based on the calculated magnitude of the local deposition rate and a scaling factor that impacts the relative rates of deposition in lateral and vertical directions.

As depicted, the process continues at in operation 1011 where the contours of the new substrate/vapor interface are provided. See, for example, the updated contoured interface 813 in FIG. 8.

Because the computational process is iterative, it may end after operation 1011 is complete. Hence, the process 1001 may include a check for completing the process. Assuming, that the completion criterion has not been met, process control loops back to operation 1003, which determines a substrate-vapor interface for the next iteration. Thereafter, operations 1005 and 1007 determine the deposition rate for each voxel on the new interface, and current iteration proceeds with operations 1009 and 1011, as described above.

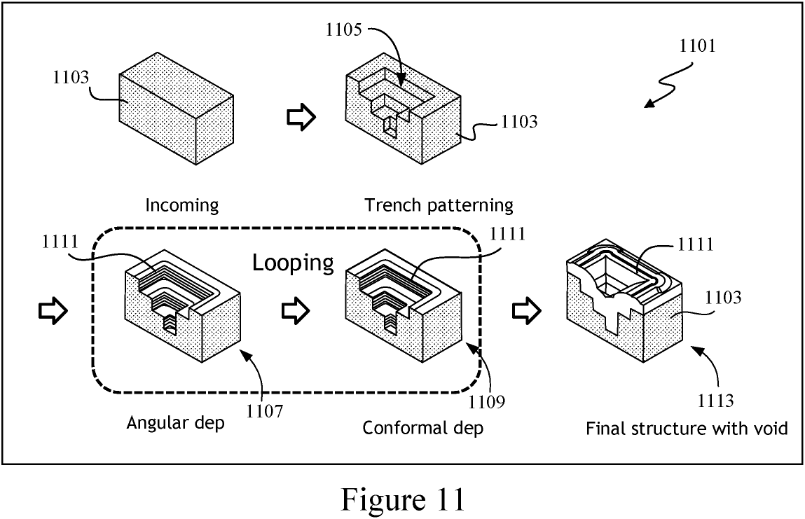

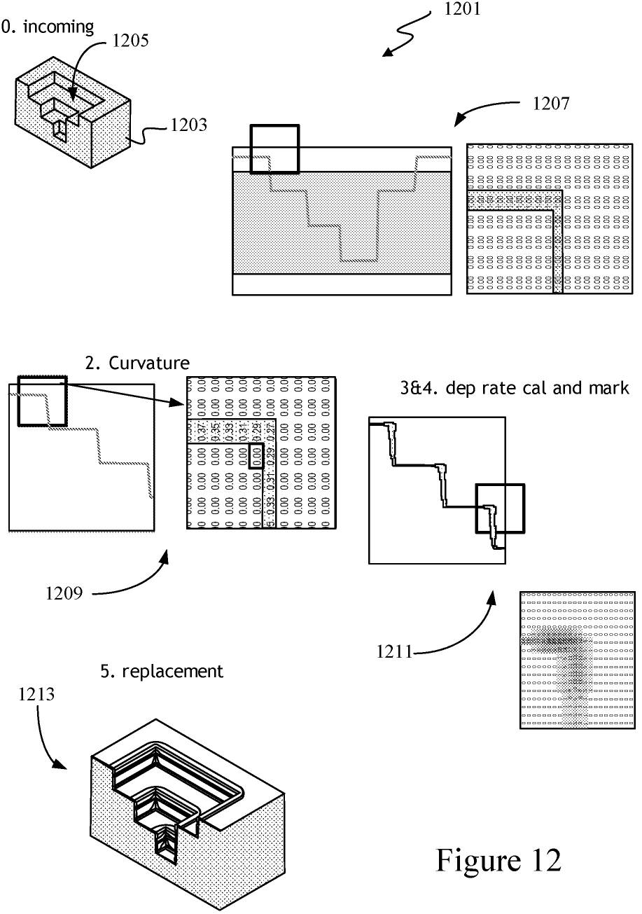

FIG. 11 and FIG. 12 illustrate an example process flow for modeling a vapor deposition process in a stepped, recessed feature. As depicted in FIG. 11, a computational process 1101 may receive an incoming feature-free substrate representation 1103. The computational process then represents a feature 1105 in the substrate representation. This may involve determining a substrate-vapor interface. In some implementations, the profile of feature 1105 is determined using a computation model of an etch process and/or a deposition process that can, in practice, produce feature 1105.

The depicted process continues with an iterative computational of vapor phase deposition in feature 1105. Each iteration involves and angle or curvature-dependent modification of feature 1105 based on computed magnitudes of local deposition rates (see block 1107) followed by a computed interface of the resulting from the local deposition rates (see block 1109). As an example, the operations leading to block 1107 may be executed by operations 1005, 1007, and 1009 in FIG. 11; see also application of geometric elements 809 in FIG. 8. As an example, an operation leading to block 1109 may be executed by operation 1011 in FIG. 11; see also generation of interface profile 813 in FIG. 8.

As illustrated, operations producing representations of deposition-modified feature 1105 are performed iteratively, gradually building up a vapor deposited material 1111. As some point in computational process 1101, after a defined number of iterations or other completion criteria, the modeled vapor deposition process concludes with a final representation of the substrate feature 1105 with fill material 1111. See representation 1113.

FIG. 12 illustrates a process 1201 of computationally modifying voxels during an iteration of a simulated vapor deposition process. The process employs a representation of an incoming model of a substrate 1203 with a recessed, stepped feature 1205. Computational process 1201 determines substrate-vapor interface positions (as voxels) where the vapor deposition process it to be simulated. See operation 1207. Computational process 1201 then determines local curvature at corners and other feature contours. See operation 1209. Using, e.g., curvature and other parameters, a model of the vapor deposition process calculates local deposition rates at voxels where curvature was determined. The simulation may mark voxels where deposition modifies the feature interface. See operation 1211. The modified feature 1205 with vapor deposited material corresponding to an iteration of computational process 1201 is represented at 1213.

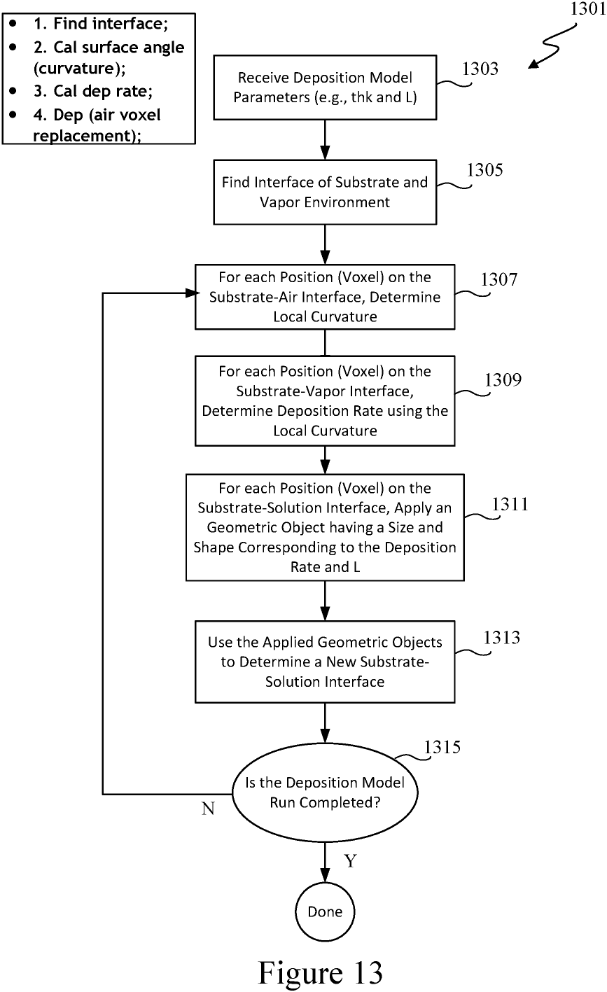

FIG. 13 illustrates an example simulation of a vapor deposition process. As illustrated, a process 1301 begins by receiving vapor deposition model parameters (e.g., thk and L). See operation 1303. These parameters may be fixed throughout the deposition process simulation or they may be adjusted in a way that accounts for progress of the deposition operation. For example, they may be adjusted as a function of iteration.

In the depicted embodiment, the computational simulation finds an initial interface (e.g., a pre-deposition interface) of the substrate on which deposition will occur and an adjacent vapor environment from which vapor deposition species will be supplied. See operation 1305.

In each iteration of the depicted embodiment, the computational simulation determines a local curvature for each of various points (voxels) on the current substrate-vapor interface. See operation 1307. Then, for each such point on the interface, the computational simulation determines a local deposition rate using the local curvature determined for that point. See operation 1309. Then, for each such point on the interface, the computational simulation applies a geometric object having a dimension or size corresponding to the deposition rate. See operation 1311. The shape of the geometric object may be set by the parameter L. With the geometric objects applied, the computational simulation may determine a new substrate-vapor interface. See operation 1313.

In the depicted embodiment, an iteration ends with operation 1313. The simulation process them applies a convergence or end point check. See operation 1315 where the simulation determines whether the deposition model run is completed. If so, the simulation terminates. If not, process control returns to operation 1307 for the next iteration of the simulation.

### Apparatus

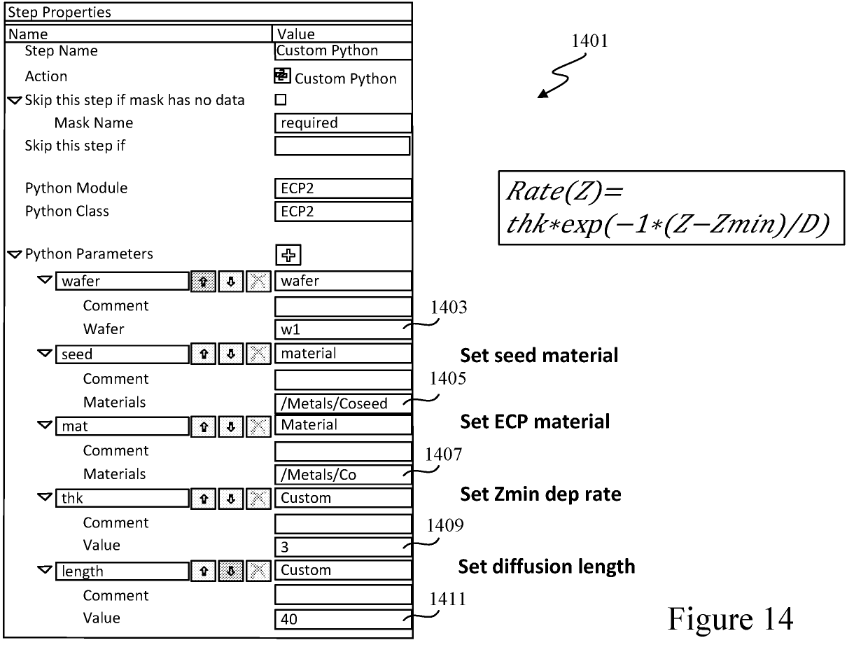

FIG. 14 depicts an example user interface display 1401 for an electrodeposition process. As illustrated, display 1401 presents fields for various user-definable parameters including fields for substrate information 1403, conductive seed material 1405, electrodeposited material 1407, deposition rate at Zmin 1409, and diffusion length 1411.

In some implementations, the seed material is defined to ensure that, at the beginning of the electrochemical deposition process, the location of the seed to solution interface is correctly determined. After the first iteration, the new interface will be the deposited metal to vapor interface.

In some implementations, wafer and/or seed material are defined (optionally as inputs via the user interface). In some implementations, the wafer and/or seed material define a different deposition regime at the beginning of the deposition process than later in the deposition process. This may be the case for any of a variety of physical or chemical reasons such as, for example, the initial deposition regime is or includes a nucleation process. In some implementations, based at least in part on the wafer and/or seed material, the deposition rate parameter (e.g., thk) is different at the beginning of the simulation (first or the first few iterations) than at a later point in the simulation (later iterations).

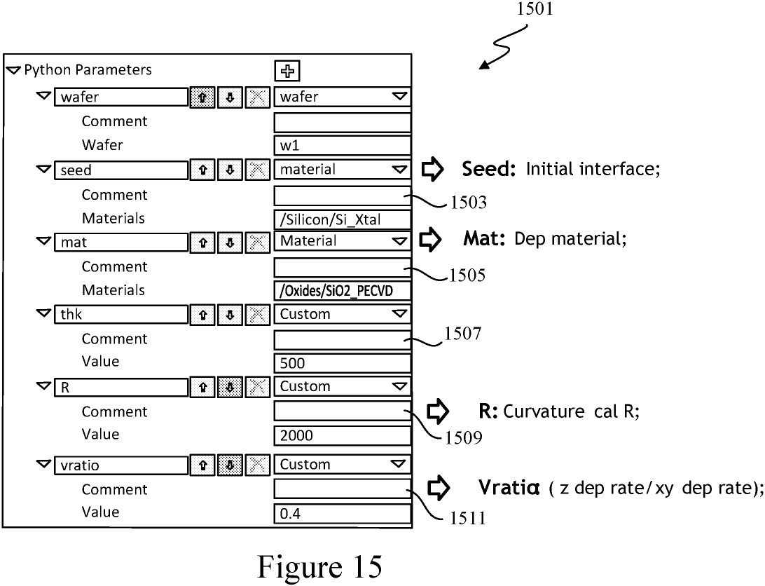

FIG. 15 depicts an example user interface display 1501 for a vapor deposition process simulation. As illustrated, display 1501 presents fields for various parameters including fields for substrate (“seed”) material information 1503 (e.g., silicon oxide or other dielectric), deposited material information 1505, maximum vapor deposition rate information 1507, curvature 1509, and a direction deposition rate ratio (L or a similar parameter as described above) 1511.

As described herein, the radius for calculating curvature and a baseline deposition rate can be selected based on real physical systems. If two corners have different deposition thk or lateral thickness L, the rate should be locally different. However, if two corners have a curvature difference but no thickness loading in the real systems, that will suggest a larger radius of curvature calculation which may ignore the local difference. Loading here refers to the thickness difference at two locations.

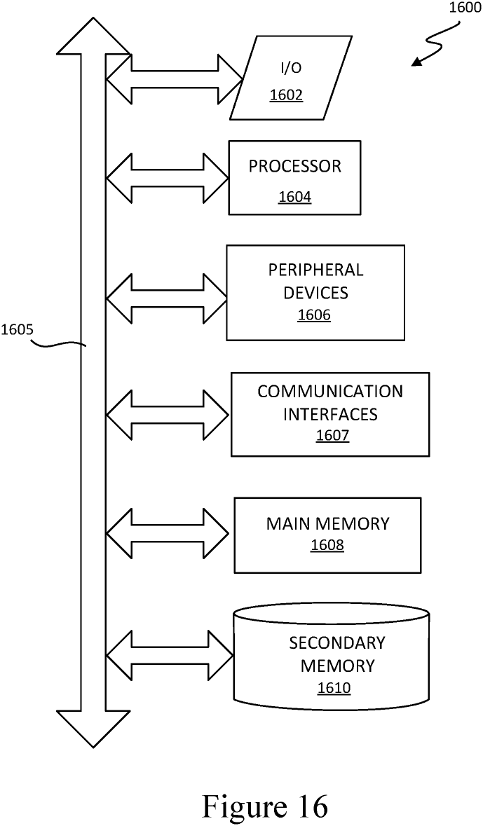

An example computer system 1600 is depicted in FIG. 16. Computing system 1600 may be, for example, PC, laptop computer, tablet computing device, server, cloud-based computational resource, virtual machines, or some other type of computing device(s) equipped with one or more processors 1604 and able to support the operations of process simulation model, optionally provided via a 2D and/or 3D modeling engine or virtual fabrication environment (not depicted).

As shown, computer system 1600 includes an input/output subsystem 1602, which may implement an interface for interacting with human users and/or other computer systems depending upon the application.

Embodiments of this disclosure may be implemented in program code on system 1600 with I/O subsystem 1602 optionally used to receive input program statements, parameter settings, and/or data from a human user (e.g., via a GUI or keyboard) and to optionally display them back to the user. The I/O subsystem 1602 may include, e.g., a keyboard, mouse, graphical user interface, a touch screen, and/or other interfaces for input. The I/O subsystem 1602 may include, e.g., an LED or other flat screen display, a speaker, and/or other interfaces for output. In some embodiments, I/O subsystem 1602 includes a display such as a display screen that is part of computing system 1600 or is separate from but communicatively coupled with computing device 1600.

Program code for interacting with a user and/or executing a process simulation model may be stored in non-transitory media such as persistent storage 1610 or memory 1608 or both. Memory 1608 and/or storage 1610 may include volatile and/or non-volatile storage such as, but not limited to, Random Access Memory (RAM), Read Only Memory (ROM), semiconductor memory, magnetic memory, and/or type of computer memory.

One or more processors 1604 configured to read program code from one or more non-transitory media and execute the code to enable the computer system to accomplish the computational methods performed by the embodiments herein, such as those involved with generating or using a process simulation model as described herein. Those skilled in the art will understand that the processor may accept source code, such as statements for executing modeling operations and/or interpret or compile the source code into machine code that is understandable at the hardware gate level of the processor. The one or more processors 1604 may have one or more cores. A bus 1605 couples the I/O subsystem 1602, the processor 1604, peripheral devices 1606, memory 1608, and persistent storage 1610.

Computing device 1600 may also be equipped with a communications interface 1607 such as a network interface so as to enable communication with other computing devices or systems.

Computing system 1600 may store and execute one or more algorithms associated with process simulation in order to perform virtual fabrication runs that predict or simulate results of a deposition process. A virtual fabrication environment may generate a number of user interfaces and views used to generate and/or display the results of virtual fabrication runs. For example, a virtual fabrication environment may be configured to display a tabular and graphical results in a 2D or 3D view. Input data to a virtual fabrication environment may include 2D/3D design data and/or program instructions for executing the simulation. Input data concerning the substrate on which the deposition process is to be modeled may be provided in an industry standard layout format such as GDS II (Graphical Design System version 2) or OASIS (Open Artwork System Interchange Standard).

Input data may also include or contain instructions for accessing a materials database including records of material types. Each material may have a name and some attributes such as a rendering color. The materials database may be stored in a separate data structure.

Embodiments of the present invention provide a virtual fabrication environment that may be configured for automatic extraction of structural measurements from the device being created. The automatic extraction of a measurement may be accomplished by specifying a virtual metrology measurement step in the process sequence at a point in the process. The output data from this virtual metrology measurement can be used to provide quantitative comparison to other modeling results or to physical metrology measurements. This virtual metrology measurement capability may allow the virtual fabrication environment to extract a physical dimension at point in the process simulation methodology.

### EXAMPLES

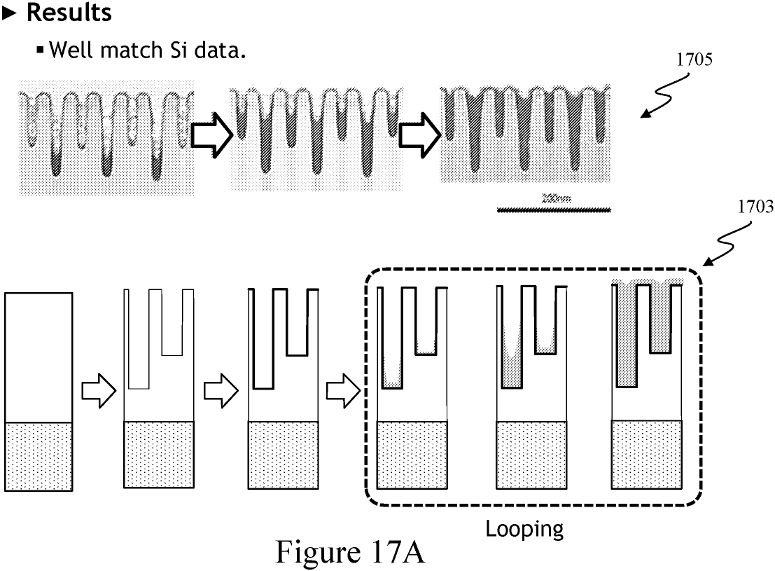

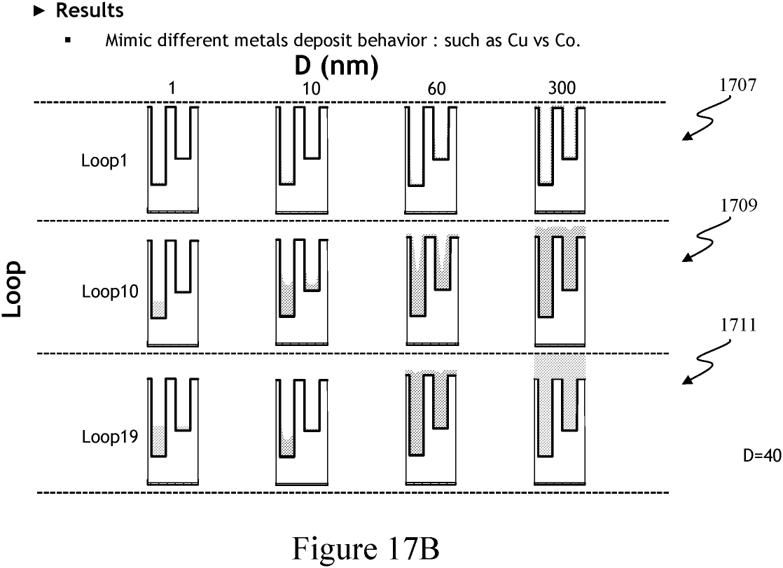

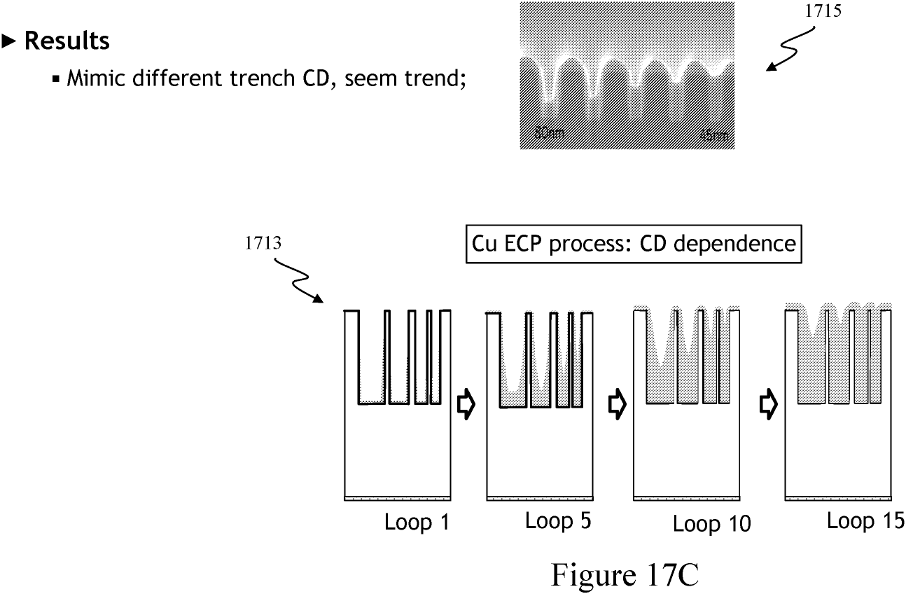

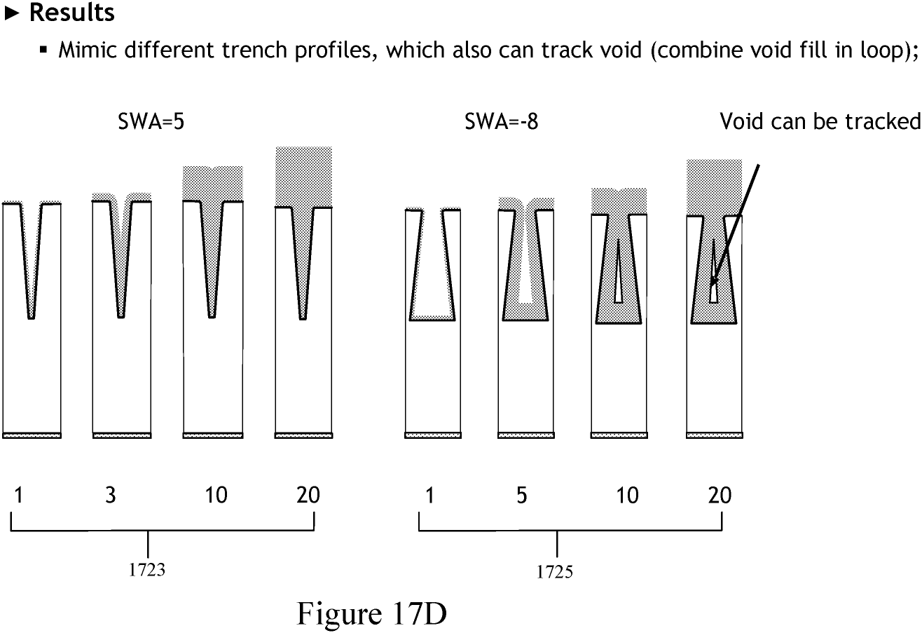

Predicted electrofill results using computational processes disclosed herein are illustrated in FIGS. 17A, 17B, 17C, and 17D. FIG. 17A illustrates that electrofill simulation results 1703 in a substrate having different feature depths match actual electrofill results shown in micrographs 1705. The model and the actual electrofill process used features having widths of approximately 20 nm and maximum depths of 150 nm. The electrodeposited material was cobalt.

FIG. 17B illustrates electrofill simulation results for multiple runs using different mass transfer parameter values (diffusion length values in this example). The different parameter values may be associated with different deposition chemistries and/or different deposition metals. In the depicted example, an electrofill model as described herein was executed over numbers of iterations (corresponding to time evolution stages). The results at 1 iteration are shown in panel 1707; the results at 10 iterations are shown in panel 1709; and the results at 19 iterations are shown in panel 1711. The results at each iteration number are shown separately for diffusion length parameter values of 1, 10, 60, and 300 nm. As would be expected, the model run employing a diffusion length of 300 nm predicted the fast fill, while the model run employing a diffusion length of 1 nm predicted the slowest fill.

FIG. 17C presents an electrofill simulation’s results 1713 in a substrate having features with different critical dimensions. As illustrated, these predicted results match actual electrofill results shown in micrographs 1715. The model and the actual electrofill process use features having critical dimensions of 45 to 80 nm. The electrodeposited material was copper.

FIG. 17D illustrates electrofill simulation results for runs using different feature profiles, particularly different side wall angles in a recessed feature. Results of a model run 1723 illustrate time evolution electrofill in a V-shaped trench having a side wall angle of 5°. Under the selected deposition parameters, the model predicted a void-free bottom-up fill. The results of a model run 1725 illustrate time evolution electrofill in a flask-shaped trench having a side wall angle of -8°. Under the selected deposition parameters, the model predicted a void-containing feature fill. The model used features having opening widths of 20 nm and depths of 100 nm. The electrodeposited material was cobalt. The time evolution of run 1723 is depicted at 1, 3, 10, and 20 iterations. The time evolution of run 1725 is depicted at 1, 5, 10, and 20 iterations. This example demonstrates the capability that the electrofill simulation process to predict voids at particular deposition settings.

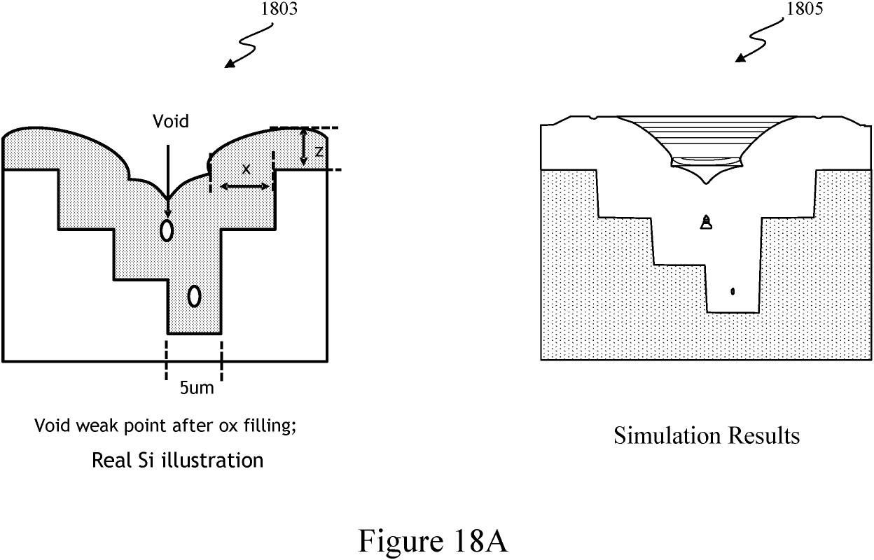

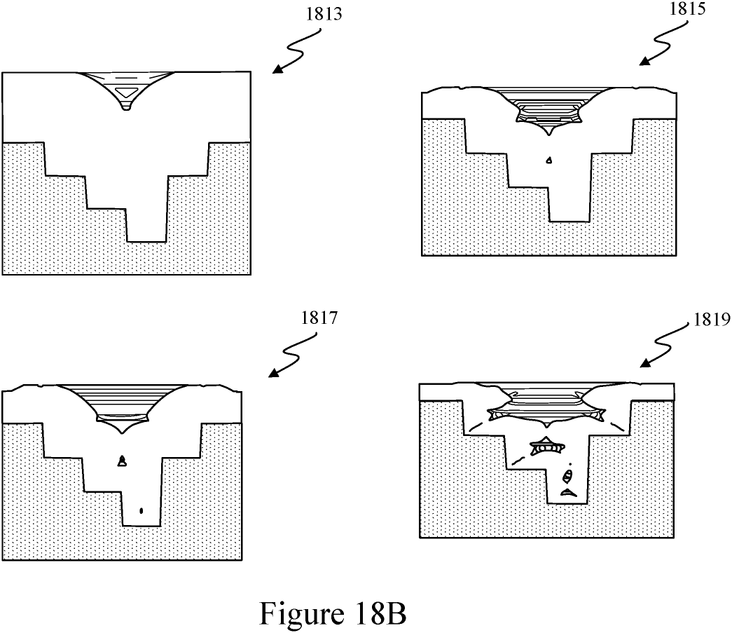

FIG. 18A presents an example comparing a simulation result with a real result for vapor depositing an oxide. An actual vapor deposition process produced the fill results shown in panel 1803. The process used a CVD fill process that filled a stepped feature having a step depth of about 4 micrometers with a silicon oxide. As shown in panel 1803, voids formed at two locations. A simulation using the above computational process and curvature-based deposition rate model for simulating vapor deposition was used. By choosing appropriate values of a maximum deposition rate (e.g., thk) and a lateral versus vertical deposition rate ratio (e.g., L), the simulation result was able to correctly identify the locations of the two voids as shown in panel 1805.

FIG. 18B illustrates flexibility of the computational simulation to match various actual vapor deposition results by choosing combinations of the adjustable parameters such as thk, R, and L. Panel 1813 depicts a void-free vapor deposition feature fill using a first combination of the adjustable parameters in a computational simulation as described herein. Panel 1815 depicts a vapor deposition feature fill having a single small void that was predicted using a second combination of the adjustable parameters in a computational simulation as described herein. Panel 1817 depicts a vapor deposition feature fill having two small voids that were predicted using a third combination of the adjustable parameters in a computational simulation as described herein. Panel 1819 depicts a vapor deposition feature fill having two large voids that were predicted using a fourth combination of the adjustable parameters in a computational simulation as described herein.

### Example Embodiments

A system, method, and/or non-transitory computer readable medium may implement or be configured to implement the following computational operations associated with electrochemical deposition: (a) defining an interface of a substrate where electrochemical deposition of a deposited material is to occur or is occurring, where the interface comprises one or more recessed or protruding features extending vertically into or above a surface of the substrate; (b) using a computational model of electrochemical deposition to determine a local deposition rate of the deposited material at multiple locations on the interface, where the computational model of electrochemical deposition computes the local deposition rate as a function of a vertical position in or on the one or more recessed or protruding features; and (c) computationally adjusting the location of the interface to produce an adjusted interface, where adjusting the interface applies the deposited material in a manner that accounts for the local deposition rate of the deposited material at the multiple locations on the interface.

In certain embodiments, operations (b) and (c) are repeated until, e.g., determining that the one or more recessed features of the surface of the substrate are fully filled with the deposited material or until determining that an overburden of the deposited material is produced over one or more recessed features of the surface of the substrate.

In certain embodiments, the computational model is configured to account for a concentration of a chemical species that varies as a function of the vertical position in or on the one or more recessed or protruding features. In some cases, the chemical species is a chemical species that adsorbs on the features on the surface of the substrate. In some cases, the chemical species comprise hydrogen ions. In some cases, the chemical species forms a concentration gradient along sidewalls of the one or more recessed or protruding features.

In certain embodiments, the computational model of electrochemical deposition comprises an exponential function of the vertical position in or on the one or more recessed or protruding features. In certain embodiments, the computational model comprises a plurality of fixed parameters, and the plurality of fixed parameters comprises a characteristic baseline deposition rate of the electrochemical deposition and a characteristic diffusion length of one or more chemical species.

In some implementations, the computational model contains only two fixed parameters. In some implementations, the computational model contains only one variable and the only one variable is the vertical position in or on the one or more recessed or protruding features.

A system, method, and/or non-transitory computer readable medium may implement or be configured to implement the following computational operations associated with vapor phase deposition: (a) defining an interface of a substrate where vapor deposition of a deposited material is to occur or is occurring, where the interface comprises one or more recessed or protruding features extending vertically into or above a surface of the substrate; (b) using a computational model of vapor deposition to determine a local deposition rate of the deposited material at multiple locations on the interface, where the computational model of vapor deposition computes the local deposition rate as a function of a local curvature in or on the one or more recessed or protruding features; and (c) computationally adjusting the location of the interface to produce an adjusted interface, where adjusting the interface applies the deposited material in a manner that accounts for the local deposition rate of the deposited material at the multiple locations on the interface.

In certain embodiments, the computational model of vapor deposition comprises a linear expression of the local curvature in or on the one or more recessed or protruding features. In certain embodiments, the computational model comprises one or more fixed parameters, and the one or more fixed parameters comprise a characteristic baseline deposition rate of the vapor deposition and a lateral deposition rate to vertical deposition rate ratio.

In certain embodiments, the computational model contains only two fixed parameters. In certain embodiments, the computational model contains only one variable, and the only one variable is the local curvature in or on the one or more recessed or protruding features.

In certain embodiments, adjusting the location of the interface comprises applying geometric objects to the multiple locations on the interface, and the geometric objects have a dimension that varies in sized based at least in part on the local deposition rate of the deposited material on the multiple locations. In certain embodiments, the geometric objects are ellipses or ellipsoids. In certain embodiments, the geometric objects have a first axis and a second axis, and a ratio of the length of the first axis to the length of the second axis corresponds to a ratio of a lateral deposition rate of the vapor deposition to a vertical deposition rate of the vapor deposition.

### Conclusion

Unless the context of this disclosure clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list, and any combination of the items in the list. The term “implementation” refers to implementations of computational and physical methods described herein, as well as to computational routines that embody algorithms, models, and/or methods described herein. In certain embodiments, numerical or mathematical values, including end points of numerical ranges, are not to be interpreted with more significant digits than presented.

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware-for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

Although the foregoing embodiments and examples have been described in some detail for purposes of clarity of understanding, it will be apparent that certain changes and modifications may be practiced within the scope of the appended claims. Embodiments disclosed herein may be practiced without some or all these details. In other instances, well-known process operations have not been described in detail to not unnecessarily obscure the disclosed embodiments. Further, while the disclosed embodiments will be described in conjunction with specific embodiments, it will be understood that the embodiments are not intended to limit the disclosed embodiments. There are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A system comprising one or more processors, wherein the system is configured to computationally execute instructions for:
(a) defining an interface of a substrate where deposition of a deposited material is to occur or is occurring, wherein the interface comprises one or more recessed or protruding features extending vertically into or above a surface of the substrate;
(b) using a computational model of the deposition to determine a local deposition rate of the deposited material at multiple locations on the interface, wherein the computational model of the deposition computes the local deposition rate as a function of one or more geometric parameters of the one or more recessed or protruding features; and
(c) computationally adjusting the location of the interface to produce an adjusted interface, wherein adjusting the interface applies the deposited material in a manner that accounts for the local deposition rate of the deposited material at the multiple locations on the interface.

2. The system of claim 1, wherein the deposition is an electrochemical deposition.

3. The system of claim 2, wherein the computational model is configured to account for a concentration of a chemical species.

4. The system of claim 3, wherein the chemical species is hydrogen ions.

5-26. (canceled)

27. A computational method comprising:
(a) defining an interface of a substrate where deposition of a deposited material is to occur or is occurring, wherein the interface comprises one or more recessed or protruding features extending vertically into or above a surface of the substrate;
(b) using a computational model of the deposition to determine a local deposition rate of the deposited material at multiple locations on the interface, wherein the computational model of the deposition computes the local deposition rate as a function of one or more geometric parameters of the one or more recessed or protruding features; and
(c) computationally adjusting the location of the interface to produce an adjusted interface, wherein adjusting the interface applies the deposited material in a manner that accounts for the local deposition rate of the deposited material at the multiple locations on the interface.

28. The computational method of claim 27, wherein the deposition is an electrochemical deposition.

29. The computational method of claim 28, wherein the computational model is configured to account for a concentration of a chemical species.

30. The computational method of claim 29, wherein the chemical species is hydrogen ions.

31-52. (canceled)

53. A non-transitory computer-readable medium storing computer executable instructions for:
(a) defining an interface of a substrate where deposition of a deposited material is to occur or is occurring, wherein the interface comprises one or more recessed or protruding features extending vertically into or above a surface of the substrate;
(b) using a computational model of the deposition to determine a local deposition rate of the deposited material at multiple locations on the interface, wherein the computational model of the deposition computes the local deposition rate as a function of one or more geometric parameters of the one or more recessed or protruding features; and
(c) computationally adjusting the location of the interface to produce an adjusted interface, wherein adjusting the interface applies the deposited material in a manner that accounts for the local deposition rate of the deposited material at the multiple locations on the interface.

54. The non-transitory computer-readable medium of claim 53, wherein the deposition is an electrochemical deposition.

55. The non-transitory computer-readable medium of claim 54, wherein the computational model is configured to account for a concentration of a chemical species.

56. The non-transitory computer-readable medium of claim 55, wherein the chemical species is hydrogen ions.

57. The non-transitory computer-readable medium of claim 54, wherein the computational model comprises a plurality of fixed parameters, and wherein the plurality of fixed parameters comprises a characteristic baseline deposition rate of the electrochemical deposition and a characteristic diffusion length of one or more chemical species.

58. The non-transitory computer-readable medium of claim 53, further comprising instructions for iteratively repeating operations (b) and (c) until determining that an overburden of the deposited material is produced over one or more recessed features of the surface of the substrate.

59. The non-transitory computer-readable medium of claim 53, wherein the deposition is a vapor deposition.

60. The c non-transitory computer-readable medium of claim 59, wherein the vapor deposition is a chemical vapor deposition.

61. The non-transitory computer-readable medium of claim 59, wherein the computational model comprises a linear expression of a local curvature in or on the one or more recessed or protruding features.

62. The non-transitory computer-readable medium of claim 59, wherein the computational model comprises one or more fixed parameters, and wherein the one or more fixed parameters comprise a characteristic baseline deposition rate of the vapor deposition and a ratio of a lateral deposition rate to a vertical deposition rate.

63. The non-transitory computer-readable medium of claim 53, further comprising instructions for iteratively repeating operations (b) and (c).

64. The non-transitory computer-readable medium of claim 63, wherein the instructions for iteratively repeating operations (b) and (c) comprises instructions for repeating operations (b) and (c) until determining that the one or more recessed features of the surface of the substrate are fully filled with the deposited material.

65. The non-transitory computer-readable medium of claim 53, wherein the computational model of the deposition is a behavioral model.

66. The non-transitory computer-readable medium of claim 53, wherein the computational model is configured to account for a concentration of a chemical species that varies as a function of the vertical position in or on the one or more recessed or protruding features.

67. The non-transitory computer-readable medium of claim 66, wherein the chemical species is a chemical species that adsorbs on the features on the surface of the substrate.

68. The non-transitory computer-readable medium of claim 53, wherein the computational model of the deposition comprises an exponential function of the vertical position in or on the one or more recessed or protruding features.

69. The non-transitory computer-readable medium of claim 53, wherein the computational model contains only two fixed parameters.

70. The non-transitory computer-readable medium of claim 53, wherein the instructions for adjusting the location of the interface comprises instructions for applying geometric objects to the multiple locations on the interface, wherein the geometric objects have a dimension that varies in size based at least in part on the local deposition rate of the deposited material on the multiple locations.

71. The non-transitory computer-readable medium of claim 70, wherein the geometric objects are circles or spheres.

72. The non-transitory computer-readable medium of claim 70, wherein the geometric objects are ellipses or ellipsoids.

73. The non-transitory computer-readable medium of claim 70, wherein the geometric objects have a first axis and a second axis and wherein a ratio of a length of the first axis to a length of the second axis corresponds to a ratio of a lateral deposition rate of a vapor deposition to a vertical deposition rate of a vapor deposition.

74. The non-transitory computer-readable medium of claim 53, wherein the computational model contains only one variable and wherein the only one variable is a local curvature in or on the one or more recessed or protruding features.

75. The non-transitory computer-readable medium of claim 53, wherein the local deposition rate is determined as a function of a local curvature in or on the one or more recessed or protruding features.

76. The non-transitory computer-readable medium of claim 53, wherein the local deposition rate is determined as a function of a vertical position in or on the one or more recessed or protruding features.

77. The non-transitory computer-readable medium of claim 53, wherein the computational model is configured to account for a concentration gradient along sidewalls of the one or more recessed or protruding features.

78. The non-transitory computer-readable medium of claim 53, wherein the computational model contains only one variable and wherein the only one variable is the vertical position in or on the one or more recessed or protruding features.
